(19) United States
(12) Patent Application Publication
(10) Pub. No.: US 2011/0037103 A1
(43) Pub. Date: Feb. 17, 2011

(54) SEMICONDUCTOR DEVICE AND METHOD OF MANUFACTURING THE SAME

(75) Inventors: Tadashi YAMAGUCHI, Kanagawa (JP); Keiichiro KASHIHARA, Kanagawa (JP); Toshiaki TSUTSUMI, Kanagawa (JP); Tomonori OKUDAIRA, Kanagawa (JP); Kotaro KIHARA, Itami (JP)

Correspondence Address: MILES & STOCKBRIDGE PC, 1751 PINNACLE DRIVE, SUITE 500, MCLEAN, VA, 22102-3833, US

(73) Assignee: RENESAS ELECTRONICS CORPORATION

(21) Appl. No.: 12/852,259

(22) Filed: Aug. 6, 2010

(30) Foreign Application Priority Data
Aug. 14, 2009 (JP) 2009-188000

(51) Int. Cl. H01L 27/105; H01L 21/8239; H01L 29/04

(52) U.S. Cl. 257/255; 438/229; 257/369; 438/233; 257/E21.645; 257/E27.081; 257/E29.004

(57) ABSTRACT

To improve performance of a semiconductor device. Over a semiconductor substrate, a plurality of p-channel type MISFETs for logic, a plurality of n-channel type MISFETs for logic, a plurality of p-channel type MISFETs for memory, and a plurality of n-channel type MISFETs for memory are mixedly mounted. At least a part of the p-channel type MISFETs for logic have each a source/drain region constituted by silicon-germanium, and all the n-channel type MISFETs for logic have each a source/drain region constituted by silicon. All the p-channel type MISFETs for memory have each a source/drain region constituted by silicon, and all the n-channel type MISFETs for memory have each a source/drain region constituted by silicon.

### CROSS-REFERENCE TO RELATED APPLICATION

The disclosure of Japanese Patent Application No. 2009-188000 filed on Aug. 14, 2009 including the specification, drawings and abstract is incorporated herein by reference in its entirety.

### BACKGROUND OF THE INVENTION

The present invention relates to a semiconductor device and a method of manufacturing the same, particularly, to a semiconductor device having a MISFET and a technique that is useful when applied to the manufacturing thereof.

Currently, the miniaturization of transistors has widely been carried out to achieve the improvement of performance thereof. The improvement of performance of transistors only by the miniaturization, however, has such a problem as the increase in cost in terms of cost-performance ratio.

Consequently, not only the improvement of the performance only by the miniaturization, but there is appearing a technique which controls a stress to improve the performance of transistors.

For example, as a technique of achieving the improvement of the performance of transistors using a stress film, there is such a technique as so-called DSL (Dual Stress Liner) as described in International Publication No. WO2002/043151 Pamphlet (Patent Document 1), in which a compression stress film is formed over a p-channel type MISFET, a tensile stress film is formed over an n-channel type MISFET, and stress is applied to the channels of both MISFETs to achieve the improvement of the performance.

Moreover, Japanese Patent Laid-Open No. 2008-053288 (Patent Document 2) discloses a technique of applying SiGe to the source/drain region of the p-channel type MISFET, to achieve the improvement of the performance.

### SUMMARY OF THE INVENTION

According to studies of the present inventor, the following was known.

A SiGe strain technique, in which the source/drain region of the p-channel type MISFET is constituted by silicon-germanium and the source/drain region constituted by silicon-germanium applies compression stress to the channel region of a p-channel type MISFET Qp1, may increase a hole mobility in the channel region of the p-channel type MISFET. This may increase an ON current flowing through the channel of the p-channel type MISFET.

In the SiGe strain technique, however, although the source/drain region constituted by silicon-germanium may be formed by allowing silicon-germanium to grow epitaxially in a trench of a Si substrate, a crystal defect occurs easily near the interface of SiGe/Si, which may increase the leak current of the MISFET caused by the crystal defect. Accordingly, the hole mobility may be improved, but, at the same time, the increase in the leak current is concerned. Consequently, in semiconductor devices on which various circuits are mixedly mounted, if the SiGe strain technique is applied uniformly to the whole semiconductor device, there is such concern that the performance of the whole semiconductor device lowers instead. Consequently, it is desired to design the transistor while taking the property of the whole semiconductor device into consideration.

Moreover, when the above-described SiGe strain technique is used, the use of a <110> channel having high sensitivity of the mobility (the hole mobility) relative to the strain is preferable. This is because the improving effect of the hole mobility may be enhanced, and the improving effect of the ON current may be enhanced, by setting the channel region of the p-channel type MISFET using the SiGe strain technique to be the <110> channel.

According to studies of the present inventor, however, when a nickel silicide layer is formed over the source/drain region of a MISFET by a salicide process, particularly in the n-channel type MISFET, it was known that NiSi₂ tends to grow abnormally from the nickel silicide layer lying over the source/drain region to the channel region. The abnormal growth leads to the increase in the leak current between the source and drain of the MISFET. And, as the result of detailed studies of the present inventor on the abnormal growth, it was known that the abnormal growth tends to occur from the nickel silicide layer in the <110> direction of the substrate Si. That is, when the <110> channel is used as the channel region, NiSi₂ particularly tends to grow abnormally from the nickel silicide layer lying over the source/drain region to the channel region.

Consequently, when trying to set the channel direction to be the <110> direction in order to enhance the effect of the use of the above-described SiGe strain technique, there occurs a concern of the increase in the leak current caused by the abnormal growth of NiSi₂ from the nickel silicide layer lying over the source/drain region to the channel region, and there is a possibility of lowering the performance of the whole semiconductor device, on the contrary.

The present invention has been made in view of the above circumstances and provides a technique capable of improving the performance of a semiconductor device.

The other purposes and the new feature of the present invention will become clear from the description of the present specification and the accompanying drawings.

The following explains briefly the outline of a typical invention among the inventions disclosed in the present application.

The semiconductor device according to a representative Example is a semiconductor device in which a plurality of p-channel type field effect transistors for logic, a plurality of n-channel type field effect transistors for logic and a plurality of p-channel type field effect transistors for memory are mixedly mounted over a semiconductor substrate. Additionally, at least a part of the p-channel type field effect transistors for logic have each a first source/drain region constituted by silicon-germanium, all the n-channel type field effect transistors for logic have each a second source/drain region constituted by silicon, and all the p-channel type field effect transistors for memory have each a third source/drain region constituted by silicon.

Further, the method of manufacturing a semiconductor device according to another representative Example is a method of manufacturing a semiconductor device having a p-channel type field effect transistor for logic in a first logic region of a semiconductor substrate, an n-channel type field effect transistor for logic in a second logic region of the semiconductor substrate, a p-channel type field effect transistor for memory in a first memory region of the semiconductor substrate, and an n-channel type field effect transistor for memory in a second memory region of the semiconductor substrate. And, it includes the step of (a) preparing the semiconductor substrate. Furthermore, it includes the step of (b) after the step (a), forming a first gate electrode of the p-channel type field effect transistor for logic in the first logic region, a second gate electrode of the n-channel type field effect transistor for logic in the second logic region, a third gate electrode of the p-channel type field effect transistor for memory in the first memory region, and a fourth gate electrode of the n-channel type field effect transistor for memory in the second memory region over the semiconductor substrate via a gate insulating film, respectively. Furthermore, it includes the step of (c) forming a trench in the first logic region and epitaxially growing a silicon-germanium region in the trench to form a first source/drain region constituted by silicon-germanium of the p-channel type field effect transistor for logic. Furthermore, it includes the step of (d) forming a second source/drain region of the n-channel type field effect transistor for logic in the second logic region, a third source/drain region of the p-channel type field effect transistor for memory in the first memory region, and a fourth source/drain region of the n-channel type field effect transistor for memory in the second memory region by ion-implanting an impurity into the semiconductor substrate, respectively. And, the trench and the silicon-germanium region are formed in the first logic region, but are not formed in the second logic region, the first memory region, or the second memory region.

The following explains briefly the effect acquired by the typical invention among the inventions disclosed in the present application.

According to the representative Example, it is possible to improve the performance of semiconductor devices.

### BRIEF DESCRIPTION OF THE DRAWINGS

FIG. 1 is a cross-sectional view of the essential part in the manufacturing process of a semiconductor device being an Example of the present invention;

FIG. 2 is a cross-sectional view of the essential part in the manufacturing process of a semiconductor device subsequent to FIG. 1;

FIG. 3 is a cross-sectional view of the essential part in the manufacturing process of a semiconductor device subsequent to FIG. 2;

FIG. 4 is a cross-sectional view of the essential part in the manufacturing process of a semiconductor device subsequent to FIG. 3;

FIG. 5 is a cross-sectional view of the essential part in the manufacturing process of a semiconductor device subsequent to FIG. 4;

FIG. 6 is a cross-sectional view of the essential part in the manufacturing process of a semiconductor device subsequent to FIG. 5;

FIG. 7 is a cross-sectional view of the essential part in the manufacturing process of a semiconductor device subsequent to FIG. 6;

FIG. 8 is a cross-sectional view of the essential part in the manufacturing process of a semiconductor device subsequent to FIG. 7;

FIG. 9 is a cross-sectional view of the essential part in the manufacturing process of a semiconductor device subsequent to FIG. 8;

FIG. 10 is a cross-sectional view of the essential part in the manufacturing process of a semiconductor device subsequent to FIG. 9;

FIG. 11 is a cross-sectional view of the essential part in the manufacturing process of a semiconductor device subsequent to FIG. 10;

FIG. 12 is a cross-sectional view of the essential part in the manufacturing process of a semiconductor device subsequent to FIG. 11;

FIG. 13 is a cross-sectional view of the essential part in the manufacturing process of a semiconductor device subsequent to FIG. 12;

FIG. 14 is an explanatory drawing showing a preferable example of the technique of a first heat treatment;

FIG. 15 is an explanatory drawing showing a preferable example of the technique of the first heat treatment;

FIG. 16 is a cross-sectional view of the essential part in the manufacturing process of a semiconductor device subsequent to FIG. 13;

FIG. 17 is a cross-sectional view of the essential part in the manufacturing process of a semiconductor device subsequent to FIG. 16;

FIG. 18 is a cross-sectional view of the essential part in the manufacturing process of a semiconductor device subsequent to FIG. 17;

FIG. 19 is a cross-sectional view of the essential part in the manufacturing process of a semiconductor device subsequent to FIG. 18;

FIG. 20 is a plan view of a semiconductor device being an Example of the present invention;

FIG. 21 is an explanatory drawing of the abnormal growth of the nickel silicide layer formed over the source/drain region;

FIG. 22 is a graph showing the yield when the nickel silicide layer is formed over the source/drain region;

FIG. 23 is a graph showing standby leak current when the nickel silicide layer is formed over the source/drain region;

FIG. 24 is an explanatory drawing of the n-channel type MISFET formed in the semiconductor device being an Example of the present invention;

FIG. 25 is a graph showing the yield when the nickel silicide layer or metal silicide layer is formed over the source/drain region of the n-channel type MISFET having the <110> channel;

FIG. 26 is a graph showing the standby leak current when the nickel silicide layer or metal silicide layer is formed over the source/drain region of the n-channel type MISFET having the <110> channel;

FIG. 27 is a cross-sectional view of the essential part in the manufacturing process of a semiconductor device being another Example of the present invention;

FIG. 28 is a cross-sectional view of the essential part in the manufacturing process of a semiconductor device subsequent to FIG. 27;

FIG. 29 is a cross-sectional view of the essential part in the manufacturing process of a semiconductor device subsequent to FIG. 28;

FIG. 30 is a cross-sectional view of the essential part in the manufacturing process of a semiconductor device subsequent to FIG. 29;

FIG. 31 is a cross-sectional view of the essential part in the manufacturing process of a semiconductor device subsequent to FIG. 30; and

FIG. 32 is a cross-sectional view of the essential part in the manufacturing process of a semiconductor device subsequent to FIG. 31.

### DETAILED DESCRIPTION OF PREFERRED EMBODIMENTS

The following embodiments will be explained, divided into plural sections or embodiments, if necessary for convenience. Except for the case where it shows clearly in particular, they are not mutually unrelated and one has relationships such as a modification, details, and supplementary explanation of some or entire of another. In the following Examples, when referring to the number of elements, etc. (including the number, a numeric value, an amount, a range, etc.), they may be not restricted to the specific number but may be greater or smaller than the specific number, except for the case where they are clearly specified in particular and where they are clearly restricted to a specific number theoretically. Furthermore, in the following Examples, it is needless to say that an element (including an element step etc.) is not necessarily indispensable, except for the case where it is clearly specified in particular and where it is considered to be clearly indispensable from a theoretical point of view, etc. Similarly, in the following Examples, when shape, position relationship, etc. of an element etc. is referred to, what resembles or is similar to the shape substantially shall be included, except for the case where it is clearly specified in particular and where it is considered to be clearly not right from a theoretical point of view. This statement also applies to the numeric value and range described above.

Hereinafter, Examples of the present invention will be described in detail on the basis of the drawings. In all the drawings for explaining the Example, the same symbol is given to the member having the same function, and a repeating explanation thereof is omitted. And, in the Example below, the explanation of the same or similar portions is not repeated in principle unless it is necessary in particular.

Further, in drawings used in the Example, hatching may be omitted even in a cross-sectional view for the sake of easy understanding of the drawing. Furthermore, hatching may be given even to a plan view for the sake of easy understanding of the drawing.

### Example 1

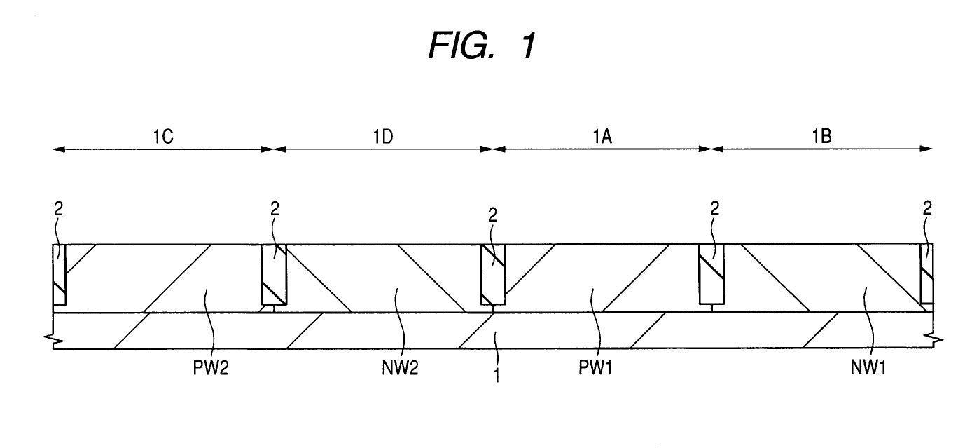

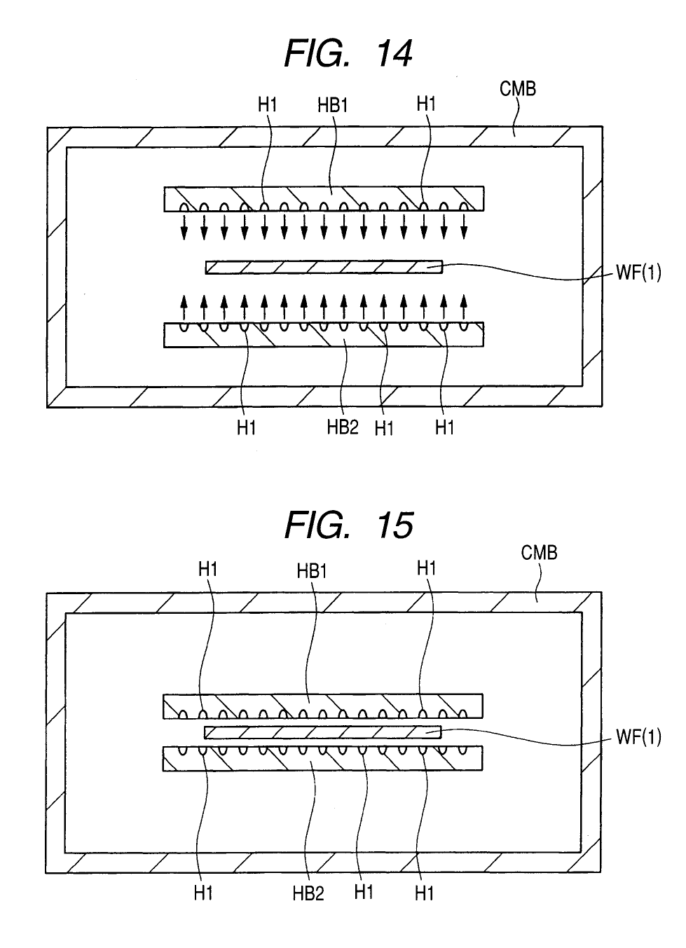

The process of manufacturing a semiconductor device in the present Example will be described with reference to drawings. FIGS. 1 to 13 and FIGS. 16 to 19 are cross-sectional views of the essential part in the process of manufacturing a semiconductor device being an Example of the present invention, here, a semiconductor device having a CMISFET (Complementary Metal Insulator Semiconductor Field Effect Transistor) (corresponding to a semiconductor device SM1 described later). FIGS. 14 and 15 are an explanatory drawing showing a preferable example of the technique of a first heat treatment.

Firstly, as shown in FIG. 1, a semiconductor substrate (semiconductor wafer) 1 made of a p-type single crystal silicon having a specific resistance of, for example, around 1 to 10 Ωcm is prepared. The semiconductor substrate 1 is a Si (100) substrate, and the semiconductor substrate 1 has the surface orientation in a (100) orientation.

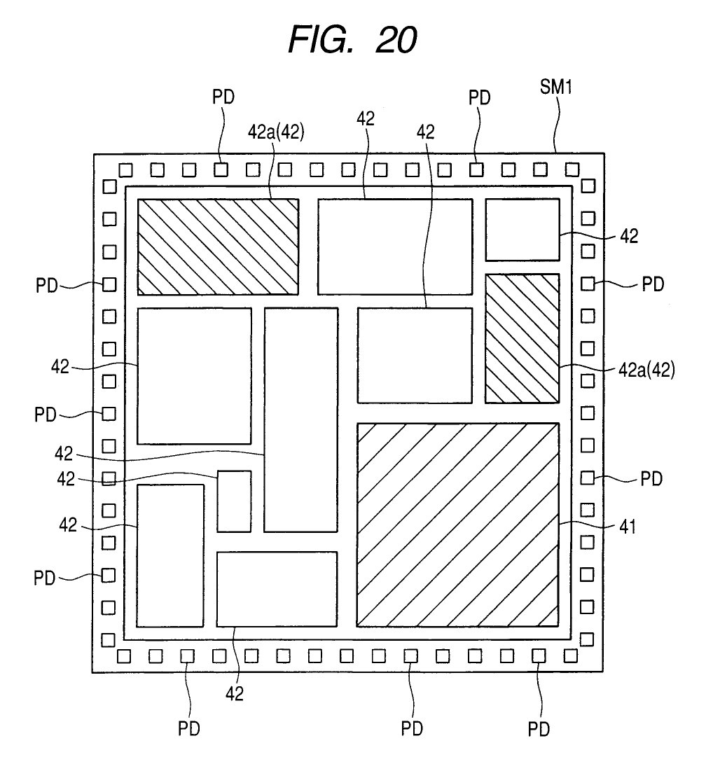

The semiconductor substrate 1 over which the semiconductor device of the Example is formed has a logic nMIS region (a second logic region) 1A being a region in which an n-channel type MISFET constituting a logic circuit is formed, and a logic pMIS region (a first logic region) 1B being a region in which a p-channel type MISFET constituting a logic circuit is formed. The semiconductor substrate 1 further has a memory nMIS region (a second memory region) 1C being a region in which an n-channel type MISFET constituting a memory (a memory cell) is formed, and a memory pMIS region (a first memory region) 1D being a region in which a p-channel type MISFET constituting a memory (a memory cell) is formed. The n-channel type MISFET formed in the memory nMIS region 1C and the p-channel type MISFET formed in the memory pMIS region 1D constitute such a memory cell array as an SRAM (Static Random Access Memory). The logic nMIS region 1A and the logic pMIS region 1B correspond to a part of a logic circuit region 42a described later (which is shown in FIG. 20 described later), and the memory nMIS region 1C and the memory pMIS region 1D correspond to a part of a memory region 41 described later (which is shown in FIG. 20 described later).

Next, in the main surface of the semiconductor substrate 1, an element isolation region 2 is formed. The element isolation region 2 is constituted by such an insulator as silicon oxide, and is formed, for example, by an STI (Shallow Trench Isolation) method or a LOCOS (Local Oxidization of Silicon) method. For example, by an insulating film embedded in a trench (an element isolation trench) formed in the semiconductor substrate 1, the element isolation region 2 may be formed.

Next, the p-type well PW1 is formed in the logic nMIS region 1A of the semiconductor substrate 1, the n-type well NW1 is formed in the logic pMIS region 1B of the semiconductor substrate 1, the p-type well PW2 is formed in the memory nMIS region 1C of the semiconductor substrate 1, and the n-type well NW2 is formed in the memory pMIS region 1D of the semiconductor substrate 1. Each of the p-type wells PW1 and PW2, and the n-type wells NW1 and NW2 may be formed by ion implantation using a photoresist film (not shown) as a mask for inhibiting ion implantation.

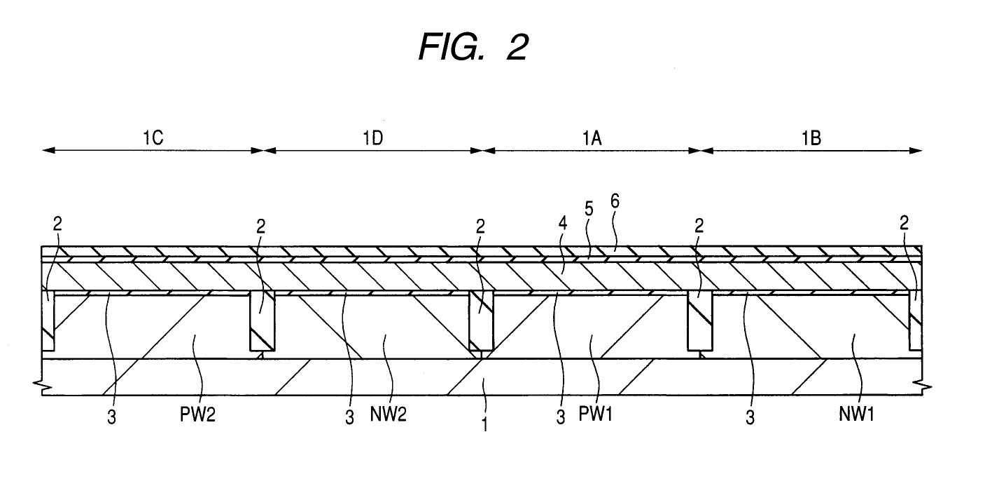

Next, after cleaning (washing) the surface of the semiconductor substrate 1 by wet etching using, for example, a hydrogen fluoride (HF) aqueous solution, or the like, as shown in FIG. 2, a gate insulating film 3 is formed over the surface of the semiconductor substrate 1 (that is, the surfaces of the p-type wells PW1 and PW2, and the n-type wells NW1 and NW2). The gate insulating film 3 is constituted, for example, by a thin silicon oxide film or the like, and may be formed, for example, by a thermal oxidation method or the like.

Next, over the whole main surface of the semiconductor substrate 1, that is, over the gate insulating film 3, a silicon film 4 is formed as an electroconductive film. The silicon film 4 may be a polycrystalline silicon film (a doped polysilicon film) or an amorphous silicon film, and, even when it is an amorphous silicon film when the film was formed, it becomes a polycrystalline silicon film by a heat treatment (for example, annealing for activating the impurity introduced for the source/drain) after the film formation. The thickness of the silicon film 4 (the deposited film thickness) may be set, for example, to be around 50 to 150 nm.

Next, over the silicon film 4, a silicon oxide film 5 is formed as an insulating film, and, over the silicon oxide film 5, a silicon nitride film 6 is formed as an insulating film. The silicon oxide film 5 and the silicon nitride film 6 may be formed, for example, using a CVD method or the like, wherein the thickness of the silicon oxide film 5 (the deposited film thickness) may be set, for example, to be around 2 to 8 nm, and the thickness of the silicon nitride film 6 may be set, for example, to be around 10 to 60 nm.

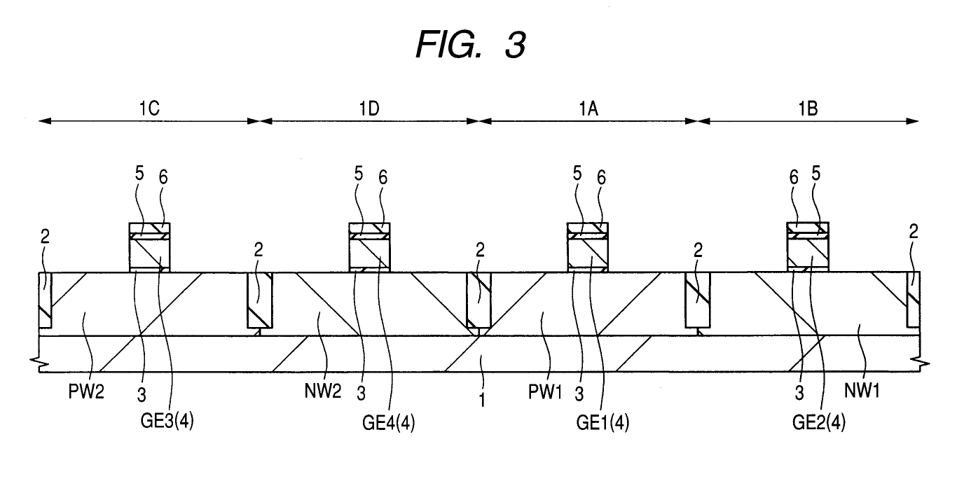

Next, as shown in FIG. 3, a laminated film of the silicon film 4, silicon oxide film 5 and silicon nitride film 6 is patterned using a photolithographic technique and a dry etching technique. This forms a patterned laminated structure (a laminated pattern) constituted by a gate electrode GE1 constituted by the patterned silicon film 4, the silicon oxide film 5 and the silicon nitride film 6 over the electrode GE1, over the surface of the p-type well PW1 in the logic nMIS region 1A via the gate insulating film 3. Moreover, a patterned laminated structure (a laminated pattern) constituted by the gate electrode GE2 constituted by the patterned silicon film 4, the silicon oxide film 5 and the silicon nitride film 6 over the electrode GE2 is formed over the surface of the n-type well NW1 in the logic pMIS region 1B via the gate insulating film 3. Further, a patterned laminated structure (a laminated pattern) constituted by the gate electrode GE3 constituted by the patterned silicon film 4, the silicon oxide film 5 and the silicon nitride film 6 over the electrode GE3 is formed over the surface of the p-type well PW2 in the memory nMIS region 1C via the gate insulating film 3. Furthermore, a patterned laminated structure (a laminated pattern) constituted by the gate electrode GE4 constituted by the patterned silicon film 4, the silicon oxide film 5 and the silicon nitride film 6 over the electrode GE4 is formed over the surface of the n-type well NW3 in the memory pMIS region 1D via the gate insulating film 3.

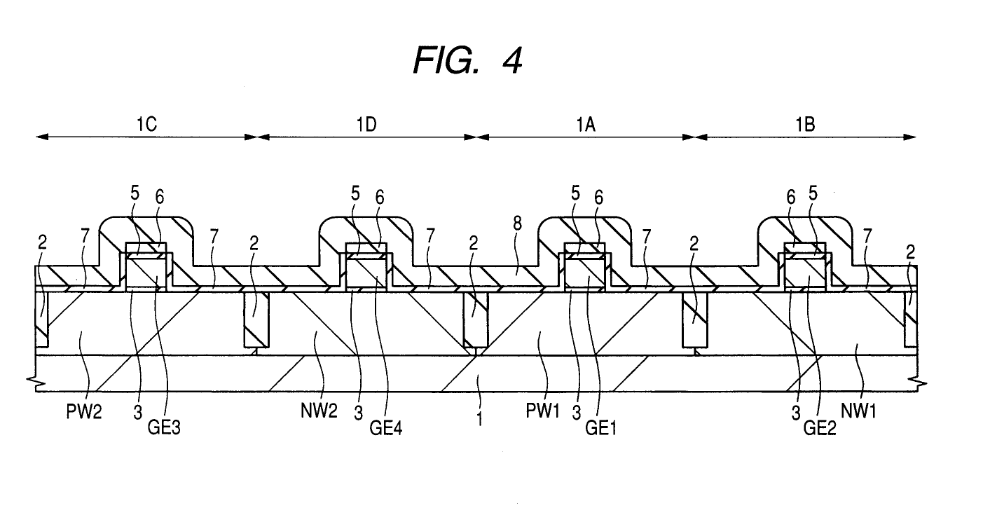

Next, as shown in FIG. 4, a silicon oxide film 7 is formed as an insulating film over the main surface of the semiconductor substrate 1 including over the side wall of the gate electrodes GE1, GE2, GE3 and GE4. The silicon oxide film 7 may be formed, for example, by a thermal oxidation method. As another form, the silicon oxide film 7 may also be formed by a CVD method, and, on this occasion, the silicon oxide film 7 is also formed over the silicon nitride film 6.

Next, over the main surface of the semiconductor substrate 1, that is, over the silicon oxide film 7, a silicon nitride film 8 is formed as an insulating film so as to cover the gate electrodes GE1, GE2, GE3 and GE4. The silicon nitride film 8 may be formed thicker than the silicon oxide film 7, for example, the silicon oxide film 7 may have a thickness (the deposited film thickness) of around 4 to 20 nm, and the silicon nitride film 8 may have a thickness (the deposited film thickness) of around 50 nm.

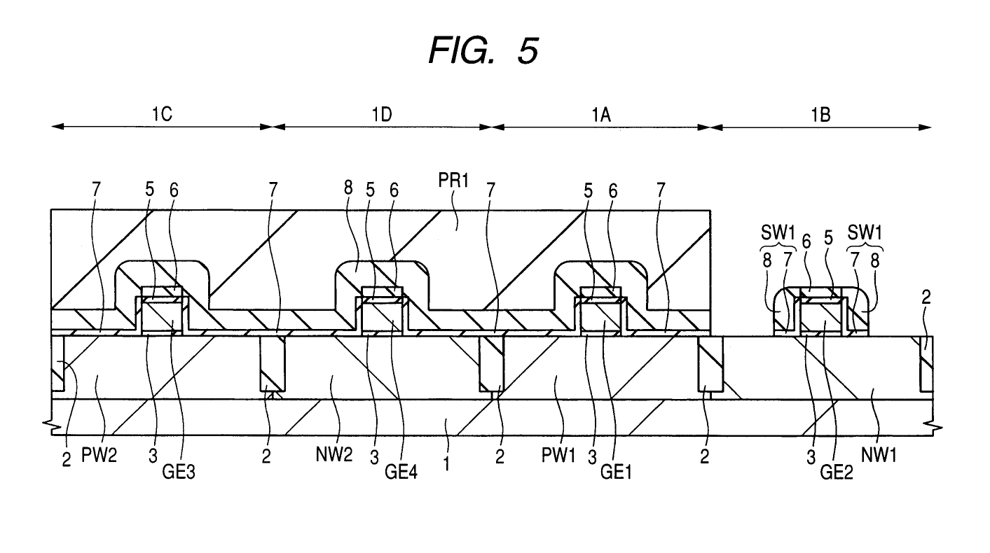

Next, over the main surface of the semiconductor substrate 1, that is, over the silicon nitride film 8, a photoresist film is coated. By exposing and developing the photoresist film, as shown in FIG. 5, a photoresist pattern (a resist pattern) PR1 is formed. The photoresist pattern PR1 is formed over the silicon nitride film 8 of the logic nMIS region 1A, memory nMIS region 1C and memory pMIS region 1D, but is not formed for the logic pMIS region 1B. Consequently, the silicon nitride film 8 in the logic nMIS region 1A, memory nMIS region 1C and memory pMIS region 1D is covered by the photoresist pattern PR1, but the silicon nitride film 8 in the logic pMIS region 1B is in such a state that it is not covered by the photoresist pattern PR1 and is exposed.

Next, the silicon nitride film 8 and silicon oxide film 7 in a region that is not covered by the photoresist pattern PR1 (that is, the logic pMIS region 1B) are subjected to an anisotropic etching (etch back). This may form, as shown in FIG. 5, a sidewall (a side wall insulating film, a side wall spacer) SW1 constituted by the silicon oxide film 7 and silicon nitride film 8 left over the side wall of the gate electrode GE2 in the logic pMIS region 1B. As the result of the anisotropic etching, (etch back), in the logic pMIS region 1B, other silicon nitride film 8 and silicon oxide film 7 than the portion left as the sidewall SW1 over the side wall of the gate electrode GE2 are removed. On the other hand, in the logic nMIS region 1A, the memory nMIS region 1C and the memory pMIS region 1D, since the photoresist pattern PR1 functions as an etching mask, the silicon nitride film 8 and silicon oxide film 7 are not etched but left. After that, the photoresist pattern PR1 is removed.

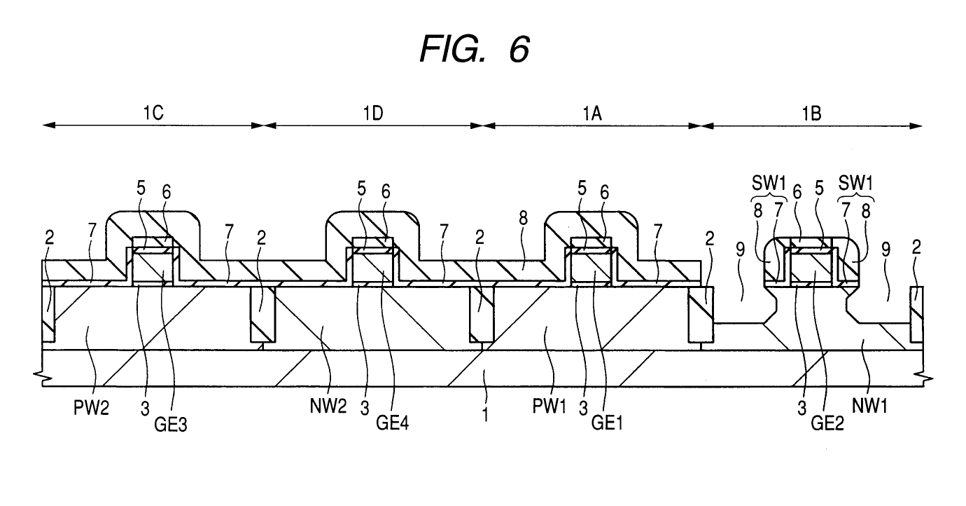

Next, as shown in FIG. 6, by performing either anisotropic or isotropic dry etching alone, or both of them in combination, in the logic pMIS region 1B, the semiconductor substrate 1 (the n-type well NW1 thereof) is etched down to a prescribed depth to form a trench (a substrate recessed portion, substrate retreated portion) 9. On this occasion, in the logic pMIS region 1B, the gate electrode GE2, the silicon oxide film 5 and silicon nitride film 6 over the electrode GE2, and the sidewall SW1 function as an etching mask. Consequently, the trench 9 is separately formed from the gate electrode GE2 by a length approximately corresponding to the thickness of the sidewall SW1 along the gate length direction of the gate electrode GE2. However, when the isotropic dry etching is performed, the trench 9 is formed near the edge portion (the edge portion on the other side of the side contacting to the gate electrode GE2) of the sidewall SW1 so as to overlap (overlap in a planar view) the sidewall SW1 to some degree. At the bottom portion and the side wall of the trench 9, a Si substrate region (the semiconductor substrate 1 in a portion constituting the n-type well NW1) is exposed. Moreover, in the process of an isotropic dry etching for forming the trench 9, in the logic nMIS region 1A, the memory nMIS region 1C and the memory pMIS region 1D, since the silicon nitride film 8 functions as an etching mask, the semiconductor substrate 1 (the p-type wells PW1 and PW2, and the n-type well NW2) is not etched, and one corresponding to the trench 9 is not formed. The depth of the trench 9 may be set to be around 20 to 80 nm.

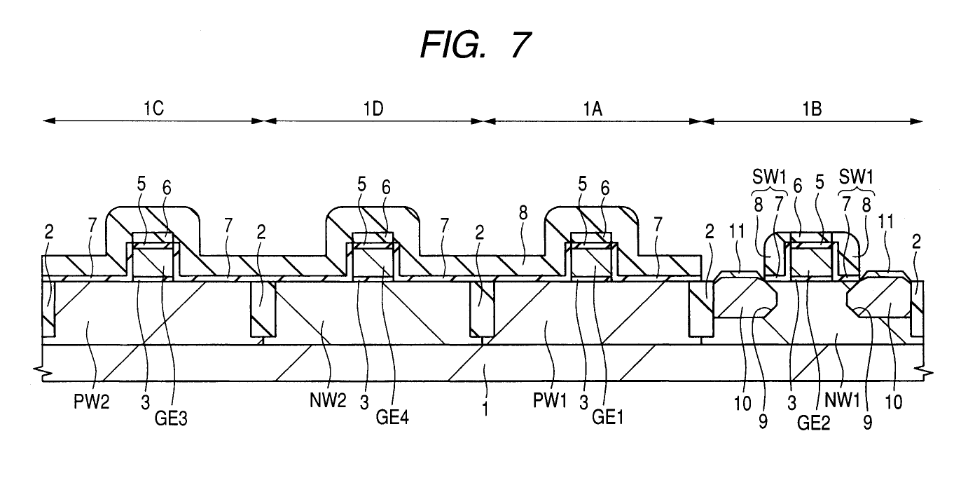

Next, as shown in FIG. 7, in the trench 9 in the logic pMIS region 1B, a silicon-germanium region (a SiGe region, silicon-germanium layer, epitaxial silicon-germanium layer) 10 is epitaxially grown, and, further continuously, a silicon region (a silicon layer, epitaxial silicon layer) 11 is epitaxially grown over the silicon-germanium region 10. Since other regions than the trench 9 are covered with the silicon nitride film 6, the sidewall SW1 or the silicon nitride film 8 (that is, the Si substrate region is not exposed), the silicon-germanium region 10 (and the silicon region 11 over the region 10) is not formed (not grown epitaxially). Accordingly, although the silicon-germanium region 10 (and silicon region 11 over the region 10) is formed in the logic pMIS region 1B, it is not formed in the logic nMIS region 1A, the memory nMIS region 1C or the memory pMIS region 1D.

The silicon-germanium region 10 is constituted, for example, by 60 to 80 atom % of Si and 20 to 40 atom % of Ge, and, when it is denoted as Si₁₋ₓGeₓ, for example, x is from 0.2 to 0.4 (0.2≦x≦0.4). Moreover, it is preferable to form the silicon-germanium region 10 so as to fill up the inside of the trench 9 in the logic pMIS region 1B, and to rise slightly, for example by 20 nm, from the main surface of the semiconductor substrate 1. The silicon-germanium region 10 may be formed, for example, in a thickness of around 40 to 100 nm, and the silicon region 11 may be formed, for example, in a thickness of around 5 to 20 nm.

Next, by oxidizing the surface layer portion of the silicon region 11 by a thermal oxidation method or the like, a silicon oxide film (not shown) is formed over the surface of the silicon region 11. The reason why the silicon oxide film is formed over the surface of the silicon region 11 is that, by allowing the silicon oxide film to function as an etching protective film when removing later the silicon nitride film 8 with hot phosphoric acid or the like, the silicon region 11 and silicon-germanium region 10 are to be protected from the etching.

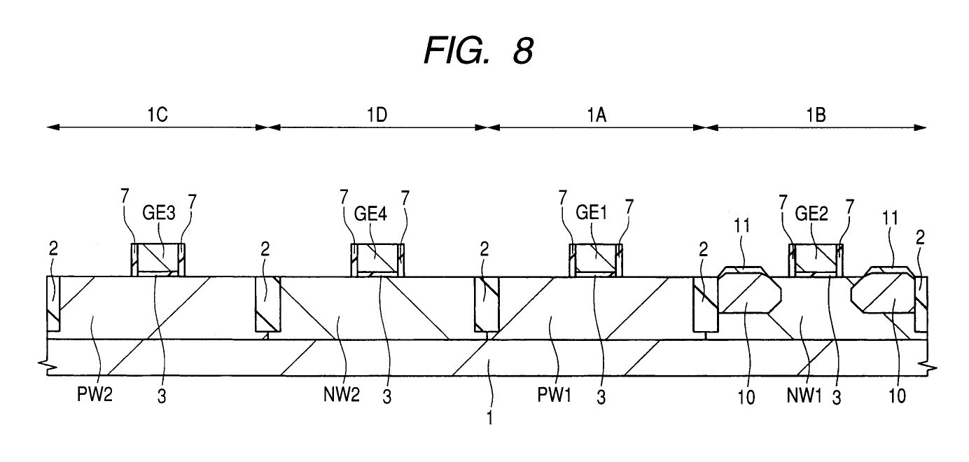

Next, as shown in FIG. 8, the silicon nitride film 8 in the logic nMIS region 1A, the memory nMIS region 1C and the memory pMIS region 1D, and the silicon nitride film 8 over the sidewall SW1 in the logic pMIS region 1B are etched using hot phosphoric acid or the like to be removed. On this occasion, the silicon nitride film 6 over the gate electrodes GE1 to GE4 may also be removed.

Next, the silicon oxide film 7 is removed by anisotropic etching, wet etching or the like. On this occasion, the silicon oxide film 5 over the gate electrodes GE1 to GE4 may also be removed. Moreover, the above-described silicon oxide film of the surface of the silicon region 11 may also be removed. When removing the silicon oxide film 7 (and the silicon oxide film 5), the use of anisotropic etching may leave the silicon oxide film 7 over the side wall of the gate electrodes GE1, GE2, GE3 and GE4 (the silicon oxide film 7 in other portions is removed). In the case where the silicon oxide film 7 is left over the side wall of the gate electrodes GE1, GE2, GE3 and GE4, when performing ion implantation for forming n⁻-type semiconductor regions EX1 and EX3, and p⁻-type semiconductor regions EX2 and EX4 to be described later, the silicon oxide film 7 over the side wall of the gate electrodes GE1 to GE4 may protect the gate electrodes GE1 to GE4.

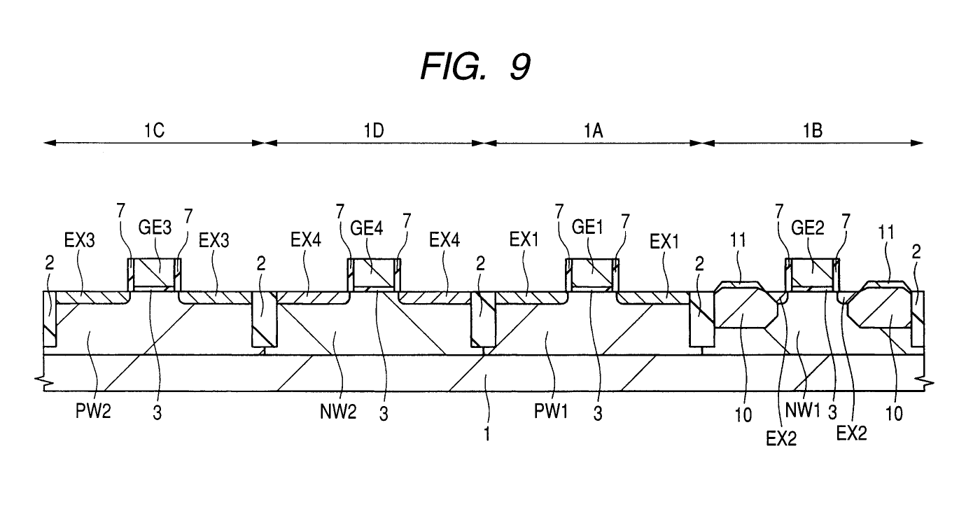

Next, as shown in FIG. 9, the n⁻-type semiconductor region (the n⁻-type extension region) EX1 is formed in regions on both sides of the gate electrode GE1 of the p-type well PW1 in the logic nMIS region 1A. Moreover, the p⁻-type semiconductor region (the p⁻-type extension region) EX2 is formed in regions on both sides of the gate electrode GE2 of the n-type well NW1 in the logic pMIS region 1B. Further, the n⁻-type semiconductor region (the n⁻-type extension region) EX3 is formed in regions on both sides of the gate electrode GE3 of the p-type well PW2 in the memory nMIS region 1C. Furthermore, the p⁻-type semiconductor region (the p⁻-type extension region) EX4 is formed in regions on both sides of the gate electrode GE4 of the n-type well NW2 in the memory pMIS region 1D.

Since the n⁻-type semiconductor region EX1 is formed by the ion implantation of an n-type impurity (for example, phosphorous or arsenic) while allowing the gate electrode GE1 to function as a mask in the logic nMIS region 1A, it is formed to be aligned with the gate electrode GE1, and, since the p⁻-type semiconductor region EX2 is formed by the ion implantation of a p-type impurity (for example, boron) while allowing the gate electrode GE2 to function as a mask in the logic pMIS region 1B, it is formed to be aligned with the gate electrode GE2. Moreover, since the n⁻-type semiconductor region EX3 is formed by the ion implantation of an n-type impurity (for example, phosphorous or arsenic) while allowing the gate electrode GE3 to function as a mask in the memory nMIS region 1C, it is formed to be aligned with the gate electrode GE3, and, since the p⁻-type semiconductor region EX4 is formed by the ion implantation of a p-type impurity (for example, boron) while allowing the gate electrode GE4 to function as a mask in the memory pMIS region 1D, it is formed to be aligned with the gate electrode GE4. The n⁻-type semiconductor region EX1 and the n⁻-type semiconductor region EX3 may be formed by the same ion implantation to reduce the number of processes, but they may also be formed by independent ion implantation. In the same manner, the p⁻-type semiconductor region EX2 and the p⁻-type semiconductor region EX3 may be formed by the same ion implantation to reduce the number of processes, but they may also be formed by independent ion implantation.

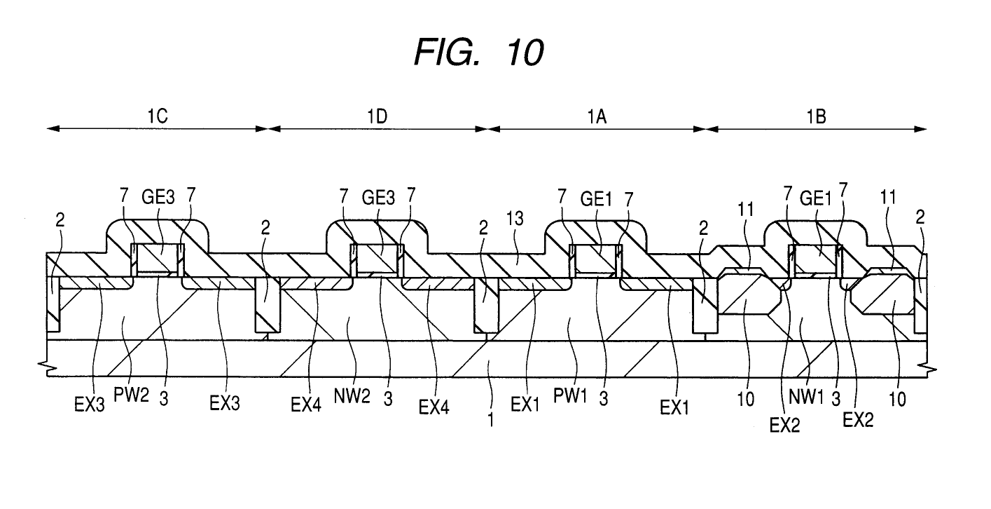

Next, as shown in FIG. 10, a silicon nitride film 13 is formed as an insulating film over the main surface of the semiconductor substrate 1 so as to cover the gate electrodes GE1, GE2, GE3 and GE4. The silicon nitride film 13 may have a thickness (the deposited film thickness), for example, set to be around 10 to 40 nm.

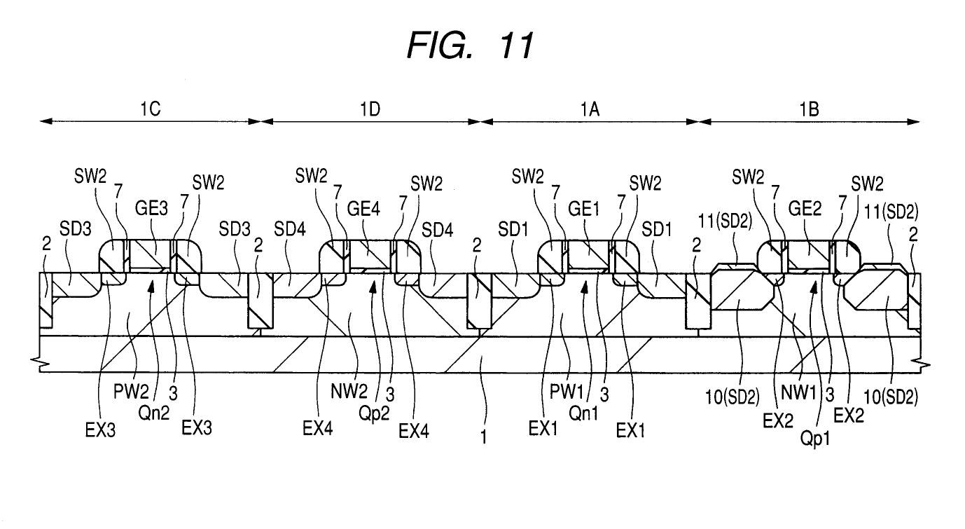

Next, the silicon nitride film 13 is anisotropically etched (etch back), as shown in FIG. 11, to form a sidewall (side wall insulating film, side wall spacer) SW2 constituted of the silicon nitride film 13 left over the side walls of the gate electrodes GE1, GE2, GE3 and GE4. The anisotropic etching (etch back) removes other silicon nitride films 13 than portions thereof left over the side walls of the gate electrodes GE1, GE2, GE3 and GE4 as the sidewall SW2. Moreover, even when the silicon nitride film 6 is left over the gate electrodes GE1, GE2, GE3 and GE4 until the process stage in FIG. 10 caused by the change of the process, the silicon nitride film 6 may be removed in the anisotropic etching process for forming the sidewall SW2.

Next, an n⁺-type semiconductor region SD1 is formed in regions on both sides of the gate electrode GE1 and the sidewall SW2 of the p-type well PW1 in the logic nMIS region 1A. Moreover, a p⁺-type semiconductor region SD2 is formed in the silicon-germanium region 10 (and in the silicon region 11 at the upper portion of the region 10) in the logic pMIS region 1B. Further, an n⁺-type semiconductor region SD3 is formed in regions on both sides of the gate electrode GE3 and the sidewall SW2 of the p-type well PW2 in the memory nMIS region 1C. Furthermore, a p⁺-type semiconductor region SD4 is formed in regions on both sides of the gate electrode GE4 and the sidewall SW2 of the n-type well NW2 in the memory pMIS region 1D.

Since the n⁺-type semiconductor region SD1 is formed by the ion implantation of an n-type impurity (for example, phosphorous or arsenic) while allowing the gate electrode GE1 and the sidewall SW2 lying over the side wall of the electrode GE1 to function as a mask for preventing the ion implantation in the logic nMIS region 1A, it is formed to be aligned with the sidewall SW2 lying over the side wall of the gate electrode GE1. Moreover, since the p⁺-type semiconductor region SD2 is formed by the ion implantation of a p-type impurity (for example, boron) while allowing the gate electrode GE2 and the sidewall SW2 lying over the side wall of the electrode GE2 to function as a mask in the logic pMIS region 1B, it is formed to be aligned with the sidewall SW2 lying over the side wall of the gate electrode GE2. Further, since the n⁺-type semiconductor region SD3 is formed by the ion implantation of an n-type impurity (for example, phosphorous or arsenic) while allowing the gate electrode GE3 and the sidewall SW2 lying over the side wall of the electrode GE3 to function as a mask in the memory nMIS region 1C, it is formed to be aligned with the sidewall SW2 lying over the side wall of the gate electrode GE3. Furthermore, since the p⁺-type semiconductor region SD4 is formed by the ion implantation of a p-type impurity (for example, boron) while allowing the gate electrode GE4 and the sidewall SW2 lying over the side wall of the electrode GE4 to function as a mask in the memory pMIS region 1D, it is formed to be aligned with the sidewall SW2 lying over the side wall of the gate electrode GE4. The n⁺-type semiconductor region SD1 and the n⁺-type semiconductor region SD3 may be formed by the same ion implantation to reduce the number of processes, but they may also be formed by independent ion implantation. In the same manner, the p⁺-type semiconductor region SD2 and the p⁺-type semiconductor region SD4 may be formed by the same ion implantation to reduce the number of processes, but they may also be formed by independent ion implantation.

After the ion implantation, an annealing treatment (activation annealing, a heat treatment) for activating the introduced impurity is performed. For example, spike annealing at around 900 to 1100° C. may be performed. This may activate the impurity introduced into the n⁻-type semiconductor regions EX1 and EX3, the p⁻-type semiconductor regions EX2 and EX4, the n⁺-type semiconductor regions SD1 and SD3, and the p⁺-type semiconductor regions SD2 and SD4 and the like.

Moreover, a p-type impurity (for example, boron) may be introduced (doped) into the silicon-germanium region 10 when forming the silicon-germanium region 10 to make the whole silicon-germanium region 10 be a p⁺-type semiconductor region. In the same manner, a p-type impurity (for example, boron) may also be introduced (doped) into the silicon region 11 when forming the silicon region 11 to make the whole silicon region 11 be a p⁺-type semiconductor region. On this occasion, the silicon-germanium region 10 in the logic pMIS region 1B may not be subjected to the ion implantation for forming the p⁺-type semiconductor region SD2, and the whole of the combination of the silicon-germanium region 10 and silicon region 11 may be considered as the p⁺-type semiconductor region SD2 for the source/drain. FIG. 11 shows a case where the whole of the combination of the silicon-germanium region 10 and the silicon region 11 is set to be the p⁺-type semiconductor region SD2 for the source/drain. When forming the p⁺-type semiconductor region SD2 in the upper layer portion of the silicon-germanium region 10 (and the silicon region 11) by the ion implantation, the lower layer portion of the silicon-germanium region 10 may have a lower impurity concentration than the upper layer portion of the silicon-germanium region 10 (a portion to be the p⁺-type semiconductor region SD2).

As described above, the structure as shown in FIG. 11 is obtained. That is, in the logic nMIS region 1A, an n-channel type MISFET (Metal Insulator Semiconductor Field Effect Transistor) Qn1 is formed as the n-channel type field effect transistor for logic. In the logic pMIS region 1B, a p-channel type MISFET Qp1 is formed as the p-channel type field effect transistor for logic. In the memory nMIS region 1C, an n-channel type MISFET Qn2 is formed as the n-channel type field effect transistor for memory. And, in the memory pMIS region 1D, a p-channel type MISFET Qp2 is formed as the p-channel type field effect transistor for memory.

Meanwhile, in FIG. 11, one MISFET is shown for each of the logic nMIS region 1A, the logic pMIS region 1B, the memory nMIS region 1C and the memory pMIS region 1D. But, actually, plural MISFETs are formed. That is, actually, plural n-channel type MISFETs Qn1 are formed in the logic nMIS region 1A, plural p-channel type MISFETs Qp1 are formed in the logic pMIS region 1B, plural n-channel type MISFETs Qn2 are formed in the memory nMIS region 1C, and plural p-channel type MISFETs Qp2 are formed in the memory pMIS region 1D, but, in FIG. 11, each one is shown on behalf of them.

In the logic nMIS region 1A, the n⁺-type semiconductor region SD1 is formed so as to have a higher impurity concentration and a deeper junction depth than the n⁻-type semiconductor region EX1, and, consequently, an n-type semiconductor region (an impurity diffusion layer) functioning as the source or drain of the n-channel type MISFET Qn1 is formed from the n⁺-type semiconductor region SD1 and the type semiconductor region EX1. Moreover, in the logic pMIS region 1B, the p⁺-type semiconductor region SD2 is formed so as to have a higher impurity concentration and a deeper junction depth than the p⁻-type semiconductor region EX2, and, consequently, a p-type semiconductor region (an impurity diffusion layer) functioning as the source or drain of the p-channel type MISFET Qp1 is formed from the p⁺-type semiconductor region SD2 and the p⁻-type semiconductor region EX2. Further, in the memory nMIS region 1C, the n⁺-type semiconductor region SD3 is formed so as to have a higher impurity concentration and a deeper junction depth than the n⁻-type semiconductor region EX3, and, consequently, the n-type semiconductor region (an impurity diffusion layer) functioning as the source or drain of the n-channel type MISFET Qn2 is formed from the n⁺-type semiconductor region SD3 and the n⁻-type semiconductor region EX3. Furthermore, in the memory pMIS region 1D, the p⁺-type semiconductor region SD4 is formed so as to have a higher impurity concentration and a deeper junction depth than the p⁻-type semiconductor region EX4, and, consequently, the p-type semiconductor region (an impurity diffusion layer) functioning as the source or drain of the p-channel type MISFET Qp2 is formed from the p⁺-type semiconductor region SD4 and the p⁻-type semiconductor region EX4.

Accordingly, the source/drain region of the n-channel type MISFETs Qn1 and Qn2 and the p-channel type MISFETs Qp1 and Qp2 has an LDD (Lightly doped Drain) structure. The n⁺-type semiconductor region SD1 may be considered as the semiconductor region for the source or drain (the source/drain region) of the n-channel type MISFET Qn1, and the p⁺-type semiconductor region SD2 may be considered as the semiconductor region for the source or drain (the source/drain region) of the p-channel type MISFET Qp1. Moreover, the n⁺-type semiconductor region SD3 may be considered as the semiconductor region for the source or drain (the source/drain region) of the n-channel type MISFET Qn2, and the p⁺-type semiconductor region SD4 may be considered as the semiconductor region for the source or drain (the source/drain region) of the p-channel type MISFET Qp2.

Next, according to need, such a process may be carried out that a silicon oxide film or the like is formed over the main surface of the semiconductor substrate 1 as an insulating film, and that, then, the silicon oxide film is left only in a region, in which the formation of a metal silicide layer 23 described later is to be hindered, using a photolithographic method and a dry etching method, or the like. For example, when forming a polysilicon resistive element (not shown) utilizing the silicon film 4 over the main surface of the semiconductor substrate 1, it is designed so that the silicon oxide film is left over the portion of the polysilicon resistive element in which the metal silicide layer 23 described later is not to be formed. This may prevent the formation of the metal silicide layer 23 in regions in which the metal silicide layer 23 described later is not to be formed. Meanwhile, in FIG. 11, since regions in which the metal silicide layer 23 described later is not to be formed (for example, polysilicon resistive element and the like) are not shown, the illustration of the process is omitted.

Next, the surface of the semiconductor substrate 1 is cleaned up using the RCA cleaning or the like. Moreover, after the RCA cleaning, a process of removing a natural oxide film of the surface of the semiconductor substrate 1 is performed using hydrofluoric acid or the like.

Next, using a salicide (Self Aligned Silicide) technique, a metal silicide layer having a low resistance (corresponding to the metal silicide layer 23 described later) is formed over the surfaces of the gate electrodes GE1 to GE4 and the source/drain regions (the n⁺-type semiconductor regions SD1 and SD3, and the p⁺-type semiconductor regions SD2 and SD4) of the logic nMIS region 1A, the logic pMIS region 1B, the memory nMIS region 1C and the memory pMIS region 1D. Hereinafter, detailed explanations will be given about the process of forming the metal silicide layer (corresponding to the metal silicide layer 23 described later).

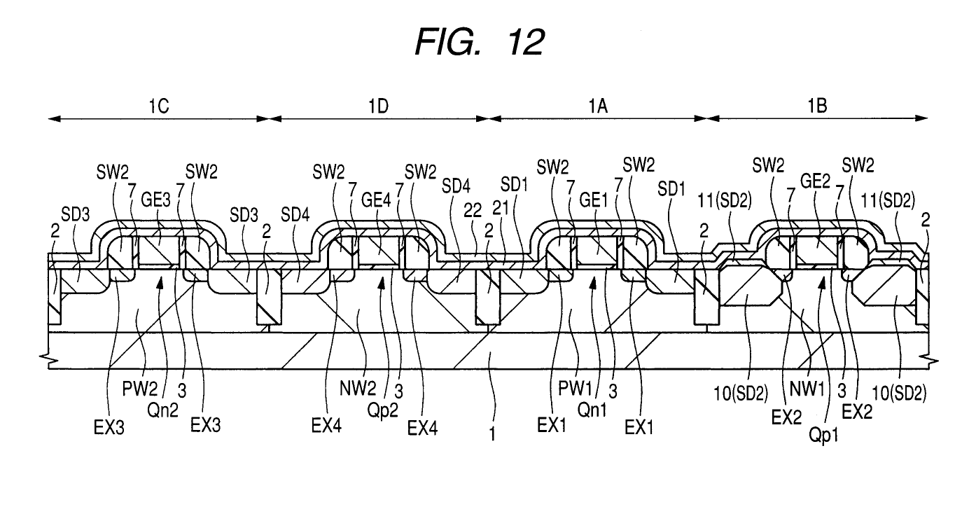

After exposing the surfaces of the gate electrodes GE1, GE2, GE3 and GE4, the n⁺-type semiconductor regions SD1 and SD3, and the p⁺-type semiconductor regions SD2 and SD4 by the process of removing a natural oxide film, as shown in FIG. 12, a nickel alloy film 21 is formed over the main surface (the whole surface) of the semiconductor substrate 1 including over the gate electrodes GE1, GE2, GE3 and GE4, the n⁺-type semiconductor regions SD1 and SD3, and p⁺-type semiconductor regions SD2 and SD4. That is, the nickel alloy film 21 is formed over the semiconductor substrate 1 including over the n⁺-type semiconductor regions SD1 and SD3, and the p⁺-type semiconductor regions SD2 and SD4 so as to cover the gate electrodes GE1, GE2, GE3 and GE4. The nickel alloy film 21 may be formed (deposited), for example, using a sputtering method.

The nickel alloy film 21 is an alloy film that contains nickel (Ni), and, in addition to nickel (Ni), contains at least one kind of element selected from the group having Pt (platinum), Pd (palladium), Hf (hafnium), V (vanadium), Al (aluminum), Er (erbium), Yb (ytterbium) and Co (cobalt).

Hereinafter, other metal elements contained in the nickel alloy film 21 than Ni are represented by Me, and, accordingly, the nickel alloy film 21 may be denoted by an Ni_{1-y}Me_{y} alloy film. Me is at least one kind of element selected from the group having Pt, Pd, Hf, V, Al, Er, Yb and Co.

In the present Example, the nickel alloy film 21 is more preferably an alloy film containing nickel (Ni) and platinum (Pt), and is most preferably a Ni—Pt alloy film (a nickel platinum alloy film) being an alloy film of Ni (nickel) and Pt (platinum), which may be represented, when defining the ratio (an atomic ratio) of Ni and Pt as 1−y:y, by a Ni_{1-y}Pt_{y} alloy film. That is, it is most preferable that the Me is Pt.

Pt concentration in the nickel alloy film 21 is preferably within the range of 3 to 7 atom, and the thickness (the deposited film thickness) of the formed nickel alloy film 21 is preferably within the range of 7 to 20 nm. Since the percentage (ratio) of Ni in the Ni_{1-y}Pt_{y} alloy film is (1−y)×100%, and the percentage (ratio) of Pt in the Ni_{1-y}Pt_{y} alloy film is y×100%, when the nickel alloy film 21 is the Ni_{1-y}Pt_{y} alloy film, y in the Ni_{1-y}Pt_{y} is preferably within a range from 0.03 to 0.07 (0.03≦y≦0.07). Meanwhile, when the percentage (ratio, concentration) of an element is denoted by % in the present application, it means % by atom.

Next, over the nickel alloy film 21, a barrier film 22 is formed (deposited). The barrier film 22 may be formed by a sputtering method or the like, and is constituted, for example, by titanium nitride (TiN) film. The barrier film 22 has such a function as preventing the oxidation of the nickel alloy film 21, and is a film that hardly reacts with the nickel alloy film 21 even when a first heat treatment described later is performed. Since the barrier film 22 has the above-described function, the formation thereof is more preferable, but, when it is unnecessary, the formation of the barrier film 22 may be omitted.

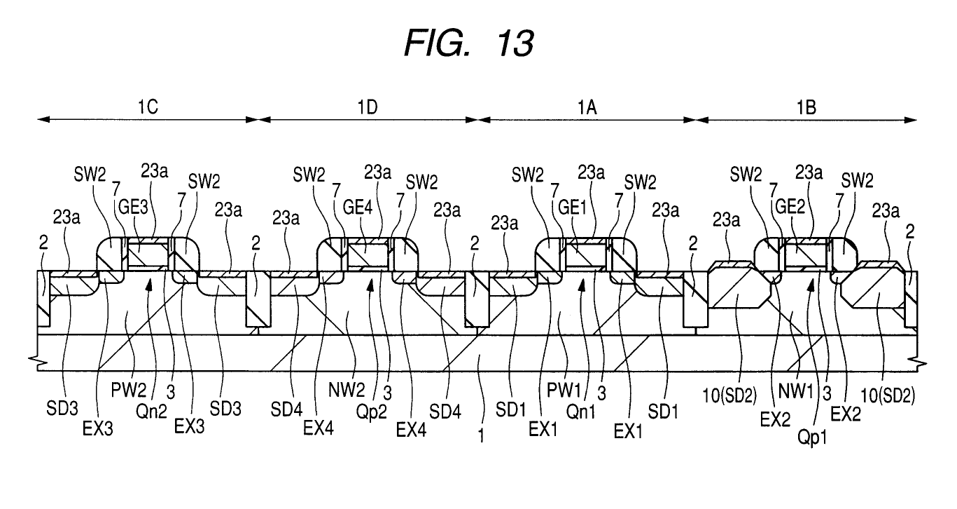

Next, the semiconductor substrate 1 is subjected to the first heat treatment (an annealing treatment). The first heat treatment selectively reacts the silicon film constituting the gate electrodes GE1 to GE4 (corresponding to the silicon film 4) with the nickel alloy film 21, the single crystalline silicon constituting the n⁺-type semiconductor regions SD1 and SD3 and the p⁺-type semiconductor region SD4 with the nickel alloy film 21, and the silicon region 11 constituting the p⁺-type semiconductor region SD2 (occasionally includes the upper layer portion of the silicon-germanium region 10) with the nickel alloy film 21. This forms, as shown in FIG. 13, a metal silicide layer 23a being a metal-semiconductor reaction layer. Here, FIG. 13 shows a stage in which, after the first heat treatment, the barrier film 22 and the unreacted nickel alloy film 21 have been removed.

Specifically, the first heat treatment reacts each of upper portions (the upper layer portions) of the gate electrodes GE1 to GE4 with the nickel alloy film 21 to form the metal silicide layer 23a for each of the surfaces (the upper layer portion) of the gate electrodes GE1 to GE4. Moreover, the first heat treatment reacts each of the upper portions (the upper layer portions) of the n⁺-type semiconductor regions SD1 and SD3, and the p⁺-type semiconductor region SD4 with the nickel alloy film 21 to form the metal silicide layer 23a for each of the surfaces (the upper layer portions) of the n⁺-type semiconductor regions SD1 and SD3, and the p⁺-type semiconductor region SD4. Further, the first heat treatment reacts the silicon region 11 (occasionally, includes the upper layer portion of the silicon-germanium region 10) with the nickel alloy film 21 in the logic pMIS region 1B to form the metal silicide layer 23a for the surface of the p⁺-type semiconductor region SD2 (the silicon-germanium region 10). Here, when the nickel alloy film 21 is a nickel platinum alloy film, the metal silicide layer 23a is constituted of silicide of Ni and Pt (nickel platinum silicide, platinum-added nickel silicide). In the first heat treatment, the metal silicide layer 23a may be formed either by reacting (consuming) the whole thickness of the nickel alloy film 21, or by reacting (consuming) a part of the whole thickness of the nickel alloy film 21 (that is, only the lower layer portion of the nickel alloy film 21).

As describe above, the first heat treatment selectively reacts the gate electrodes GE1 to GE4, the n⁺-type semiconductor regions SD1 and SD3, and the p⁺-type semiconductor regions SD2 and SD4 with the nickel alloy film 21 to form the metal silicide layer 23a including silicide of a metal element constituting the nickel alloy film 21, but, at the stage in which the first heat treatment is performed, the metal silicide layer 23a does not have a phase of Ni_{1-y}Me_{y}Si. That is, at the stage of performing the first heat treatment, the metal silicide layer 23a has a more metal rich silicide phase than the Ni_{1-y}Me_{y}Si phase (that is, the content obtained by summing Ni and Me is more than that of the Ni_{1-y}Me_{y}Si phase), and preferably has a (Ni_{1-y}Me_{y})₂Si phase (here, 0<y<1). Accordingly, the first heat treatment may preferably be performed at a heat treatment temperature that leads to the metal silicide layer 23a having the (Ni_{1-y}Me_{y})₂Si phase, but that does not lead to the layer 23a having the Ni_{1-y}Me_{y}Si phase.

The first heat treatment is preferably a low-temperature short-time annealing. Specifically, in the first heat treatment, the heat treatment temperature is preferably within the range of 200 to 300° C., more preferably within the range of 240 to 280° C., and the heat treatment time is preferably within the range of 10 to 60 seconds. Moreover, the first heat treatment is performed preferably in an atmosphere of nitrogen (N₂) gas, and it may also be performed in an atmosphere of an inert gas (such as argon (Ar) gas, neon (Ne) gas or helium (He) gas), or of a mixed gas of the inert gas and nitrogen gas.

In the Example, it is important to control the heat treatment temperature and the heat treatment time of the first heat treatment within the above ranges, respectively, so as not to give an excess first heat treatment. But, from the standpoint of reacting the nickel alloy film 21 with the gate electrodes GE1 to GE4, the n⁺-type semiconductor regions SD1 and SD3, and the p⁺-type semiconductor regions SD2 and SD4, in the first heat treatment, the heat treatment temperature is preferably 200° C. or more, and the heat treatment time is 10 seconds or more.

FIGS. 14 and 15 are explanatory drawings showing a preferable example of the technique of the first heat treatment.

In order to perform the first heat treatment, firstly, as shown in FIG. 14, a semiconductor wafer WF corresponding to the semiconductor substrate 1 is set between a pair of heater blocks (heating blocks) HB1 and HB2 in a chamber CMB for the heat treatment having a nitrogen gas (or an inert gas) atmosphere. Respective heater blocks HB1 and HB2 have such a constitution that is provided with a built-in heater (a heating mechanism) or the like to make the heating possible to an intended temperature, and is provided with plural ejection holes (ejection openings) H1 capable of ejecting (discharging) nitrogen gas (or the inert gas) toward the semiconductor wafer WF. In FIG. 14, for the purpose of easy understanding, the flow of nitrogen gas (or the inert gas) is schematically shown by arrows when nitrogen gas (or the inert gas) is ejected from the ejection holes H1 of the heater blocks HB1 and HB2.

In order to subject the semiconductor wafer WF to a heat treatment (the first heat treatment), after heating the heater blocks HB1 and HB2 to a prescribed temperature, the heated heater blocks HB1 and HB2 are brought closer to the front and back sides of the semiconductor wafer WF from a state in FIG. 14 to a state in FIG. 15, and the semiconductor wafer WF is heated by the heat from the close (but noncontact) heater blocks HB1 and HB2. On this occasion, the heater blocks HB1 and HB2 blow the heated nitrogen gas (or the inert gas) against the semiconductor wafer WF from the ejection holes H1, which also contributes to heating the semiconductor wafer WF. Meanwhile, in FIG. 15, for the purpose of preventing that the drawing becomes hard to understand, the illustration of flow of the nitrogen gas (or the inert gas) blown from the ejection holes H1 of the heater blocks HB1 and HB2 against the semiconductor wafer WF is omitted.

After heating (heat treating) the semiconductor wafer WF at a prescribed temperature for a prescribed time, by moving the heater blocks HB1 and HB2 apart from the semiconductor wafer WF, as from the state in FIG. 15 to the state in FIG. 14, the heat treatment (heating) of the semiconductor wafer WF is terminated. As the result of the above, the first heat treatment at a comparatively low temperature (preferably within the range of 200 to 300° C., more preferably within the range of 240 to 280° C.) and for a short time (preferably 10 to 60 seconds) may be performed. The heat treatment temperature of the first heat treatment may be controlled by adjusting the temperatures of the heater blocks HB1 and HB2, and the heat treatment time of the first heat treatment may be controlled by adjusting the time of setting the heater blocks HB1 and HB2 to be close to the front and rear sides of the semiconductor wafer WF.

The first heat treatment may also be performed by lamp annealing or the like, but, when trying to perform a heat treatment of such a low temperature as around 260° C. by lamp heating, the controllability of the heat treatment temperature is not so good. In contrast, as described above, as the result of heating the semiconductor wafer WF by setting the heated heater blocks HB1 and HB2 to be close to the semiconductor wafer WF, even in a heat treatment at such a low temperature as around 260° C., it is possible to improve the controllability of the heat treatment temperature, to actualize the first heat treatment more appropriately.

After forming the metal silicide layer 23a by the first heat treatment, by performing a wet cleaning treatment using, for example, a sulfuric acid hydrogen peroxide mixture or the like, the barrier film 22 and the unreacted nickel alloy film 21 (that is, the nickel alloy film 21 that did not react with the gate electrodes GE1 to GE4, the n⁺-type semiconductor regions SD1 and SD3, and the p⁺-type semiconductor regions SD2 and SD4) in the first heat treatment process are removed. On this occasion, although the unreacted nickel alloy film 21 is removed, the metal silicide layer 23a is left over the surfaces of the gate electrodes GE1 to GE4, the n⁺-type semiconductor regions SD1 and SD3, and the p⁺-type semiconductor regions SD2 and SD4. FIG. 13 shows a stage in which the barrier film 22 and unreacted nickel alloy film 21 have been removed by the wet cleaning treatment.

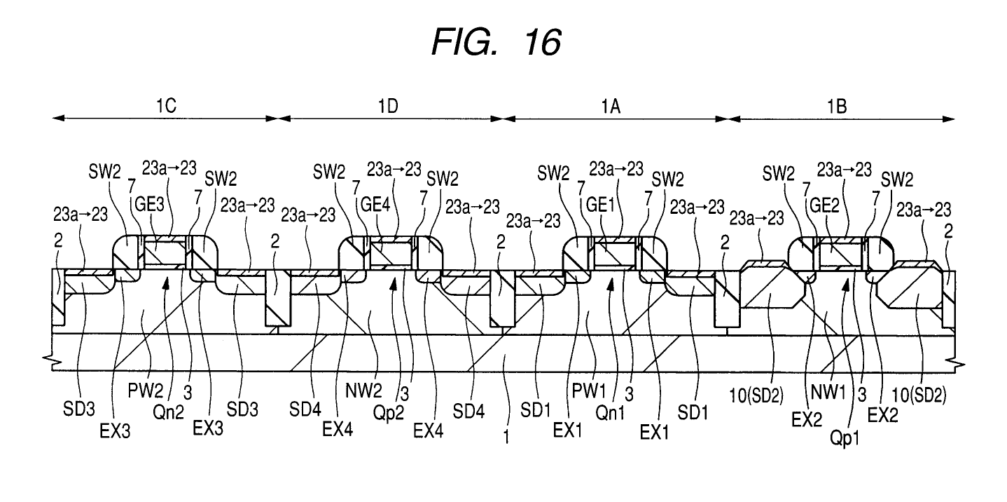

Next, the semiconductor substrate 1 is subjected to a second heat treatment (an annealing treatment). By performing the second heat treatment, as shown in FIG. 16, the metal silicide layer 23a having the (Ni_{1-y}Me_{y})₂Si phase formed by the first heat treatment is changed into the metal silicide layer 23 having the Ni_{1-y}Me_{y}Si phase, to form the stable metal silicide layer 23 having the composition ratio of the metal element (obtained by summing Ni and Me) and Si that is closer to the stoichiometric ratio of 1:1.

That is, the metal silicide layer 23a having the (Ni_{1-y}Me_{y})₂Si phase is further reacted with the Si in the gate electrodes GE1 to GE4, the n⁺-type semiconductor regions SD1 and SD3, and the p⁺-type semiconductor regions SD2 and SD4 by the second heat treatment. This forms the metal silicide layer 23 constituted by the Ni_{1-y}Me_{y}Si phase, which is more stable and has a lower resistivity than the (Ni_{1-y}Me_{y})₂Si phase, over the surface (the upper layer portion) of the gate electrodes GE1 to GE4, the n⁺-type semiconductor regions SD1 and SD3, and the p⁺-type semiconductor regions SD2 and SD4. Accordingly, both of the metal silicide layer 23a before the second heat treatment and the metal silicide layer 23 after the second heat treatment are constituted by silicide of Ni and the metal element Me, but the metal silicide layer 23a has the (Ni_{1-y}Me_{y})₂Si phase, and the metal silicide layer 23 has the Ni_{1-y}Me_{y}Si phase.

Since it is necessary to perform the second heat treatment at a temperature capable of changing the metal silicide layer 23a into the metal silicide layer 23 having the Ni_{1-y}Me_{y}Si phase, the heat treatment temperature of the second heat treatment is necessarily set to be at least higher than the heat treatment temperature of the first heat treatment. Moreover, in order to avoid the change of the metal silicide layer 23 into a Ni_{1-y}Me_{y}Si₂ phase having a higher resistivity than the Ni_{1-y}Me_{y}Si phase, the second heat treatment is preferably performed at a heat treatment temperature that changes the metal silicide layer 23a into the Ni_{1-y}Me_{y}Si phase, but does not change it into the Ni_{1-y}Me_{y}Si₂ phase. Specifically, in the second heat treatment, the heat treatment temperature is preferably within the range of 400 to 600° C., more preferably within the range of 500 to 550° C., and the heat treatment time is preferably 30 seconds or less. Moreover, from the standpoint of forming more reliably the metal silicide layer 23 having the Ni_{1-y}Me_{y}Si phase, the heat treatment time of the second heat treatment is preferably 5 seconds or more. The atmosphere when performing the second heat treatment is preferably a nitrogen (N₂) gas atmosphere, but the treatment may be performed in an inert gas (for example, argon (Ar) gas, neon (Ne) gas or helium (He) gas) atmosphere, or in a mixed gas atmosphere of the inert gas and nitrogen gas. Since the second heat treatment is a heat treatment at a higher temperature as compared with the first heat treatment, the heat treatment temperature is easily controlled, and the second heat treatment may be performed using such RTA method as lamp annealing. Moreover, the second heat treatment may also be performed, as with the first heat treatment, by the heat treatment method described above with reference to FIGS. 14 and 15.

Meanwhile, the Ni_{1-y}Me_{y}Si phase has a lower resistivity as compared with the (Ni_{1-y}Me_{y})₂Si phase and the Ni_{1-y}Me_{y}Si₂ phase. After the second heat treatment process, too, (until the end of manufacturing the semiconductor device), the metal silicide layer 23 is maintained in the Ni_{1-y}Me_{y}Si phase having a low resistivity, and, even in manufactured semiconductor devices (for example, even in such a state as a semiconductor chip (a semiconductor device SM1 described later) by cutting the semiconductor substrate 1 into pieces), the metal silicide layer 23 keeps to have the Ni_{1-y}Me_{y}Si phase having a low resistivity.

As described above, the metal silicide layer 23 having the Ni_{1-y}Me_{y}Si phase is formed over the surfaces (the upper layer portion) of respective gate electrodes GE1 to GE4 and respective source/drain regions of the n-channel type MISFET Qn1 in the logic nMIS region 1A, the p-channel type MISFET Qp1 in the logic pMIS region 1B, the n-channel type MISFET Qn2 in the memory nMIS region 1C, and the p-channel type MISFET Qp2 in the memory pMIS region 1D.

The metal silicide layer 23 formed over each of the gate electrodes GE1, GE2, GE3 and GE4 of the n-channel type MISFETs Qn1 and Qn2, and the p-channel type MISFETs Qp1 and Qp2 is a metal silicide layer having the Ni_{1-y}Me_{y}Si phase containing Ni, the metal element Me and Si as constituent elements.

Also, the metal silicide layer 23 formed over the source/drain region of the n-channel type MISFETs Qn1 and Qn2, and p-channel type MISFET Qp2 (that is, the n⁺-type semiconductor regions SD1 and SD3, and the p⁺-type semiconductor region SD4) is a metal silicide layer having the Ni_{1-y}Me_{y}Si phase containing Ni, the metal element Me and Si as constituent elements.

The metal silicide layer 23 formed over the source/drain region of the p-channel type MISFET Qp1 in the logic pMIS region 1B (that is, the p⁺-type semiconductor region SD2), however, occasionally further contains Ge, in addition to Ni, the metal element Me and Si. This is such a case where the silicon-germanium region 10 also contributes to the reaction (generation of the metal silicide layer 23a or 23) when the metal silicide layer 23a is formed in the first heat treatment, or the metal silicide layer 23 is formed in the second heat treatment.

That is, when the silicon region 11 has sufficient thickness for forming the metal silicide layer 23, in the logic pMIS region 1B, the silicon region 11 reacts (a silicidation reaction) in the first and second heat treatments, but the silicon-germanium region 10 does not react. In this case, the metal silicide layer 23 formed over the source/drain region of the p-channel type MISFET Qp1 in the logic pMIS region 1B (that is, the p⁺-type semiconductor region SD2) has the same composition as the metal silicide layer 23 formed over the source/drain region of the n-channel type MISFETs Qn1 and Qn2, and the p-channel type MISFET Qp2 (that is, the n⁺-type semiconductor regions SD1 and SD3, and the p⁺-type semiconductor region SD4), that is, contains no Ge. Instead, in the logic pMIS region 1B, thin silicon region 11 occasionally remains between the silicon-germanium region 10 and the metal silicide layer 23.

On the other hand, when the silicon region 11 does not have a sufficient thickness for forming the metal silicide layer 23, in the logic pMIS region 1B, not only the silicon region 11 but also a part (the upper layer portion) of the silicon-germanium region 10 reacts in both the first and second heat treatments, or in the second heat treatment alone. In this case, the metal silicide layer 23 formed over the source/drain region of the p-channel type MISFET Qp1 in the logic pMIS region 1B (that is, the p⁺-type semiconductor region SD2) further contains Ge, in addition to Ni, the metal element Me and Si. That is, the metal silicide layer 23 formed over the source/drain region of the p-channel type MISFET Qp1 in the logic pMIS region 1B (that is, p⁺-type semiconductor region SD2) becomes the metal silicide layer 23 having a Ni_{1-y}Me_{y}Si₁₋ₓGe_{z} phase, and no silicon region 11 remains between the silicon-germanium region 10 and the metal silicide layer 23 having the Ni_{1-y}Me_{y}Si_{1-z}Ge_{z} phase. Moreover, in the first heat treatment, when a part (the upper layer portion) of the silicon-germanium region 10, in addition to the silicon region 11, reacts with the nickel alloy film 21, the metal silicide layer 23a formed over the source/drain region of the p-channel type MISFET Qp1 (that is, the p⁺-type semiconductor region SD2) also contains Ge in addition to Ni, the metal element Me and Si, to become the metal silicide layer 23a having a (Ni_{1-y}Me_{y})₂Si_{1-z}Ge, phase. The metal silicide layer 23a having the (Ni_{1-y}Me_{y})₂Si_{1-z}Ge_{z} phase and the metal silicide layer 23 having the Ni_{1-y}Me_{y}Si_{1-z}Ge_{z} phase may also be referred to as metal silicon-germanium, metal germanium silicide, or metal silicon germanide.

As described above, the metal silicide layer 23a or 23 formed over the source/drain region of the p-channel type MISFET Qp1 in the logic pMIS region 1B (that is, p⁺-type semiconductor region SD2) occasionally contain Ge, and, in this case, they have such a composition that a part of Si of the metal silicide layer 23a or 23 formed over the source/drain region of the n-channel type MISFETs Qn1 and Qn2, and the p-channel type MISFET Qp2 has been substituted by Ge.

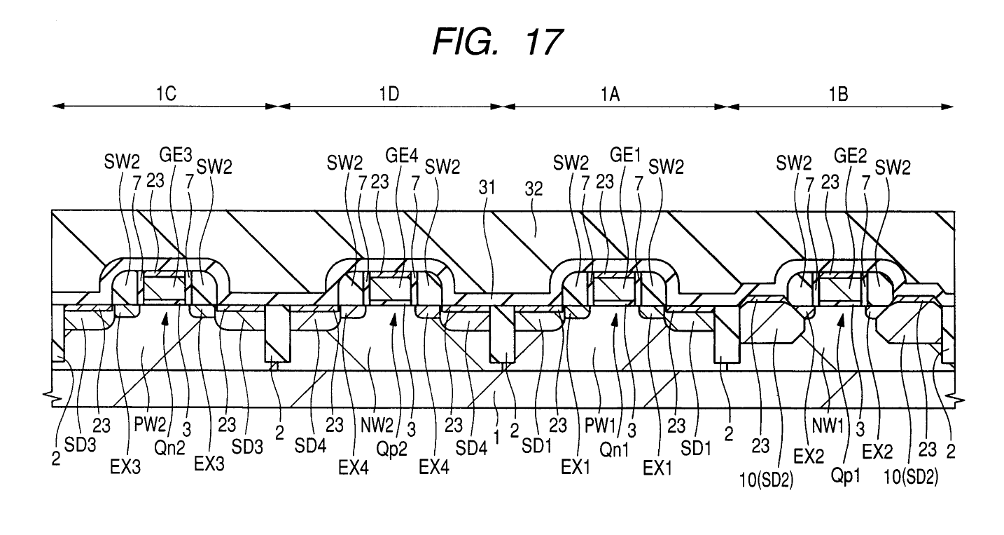

After the formation of the metal silicide layer 23 as described above, as shown in FIG. 17, an insulating film 31 is formed over the whole main surface of the semiconductor substrate 1, that is, over the main surface of the semiconductor substrate 1 including the logic nMIS region 1A, the logic pMIS region 1B, the memory nMIS region 1C and the memory pMIS region 1D. The insulating film 31 is formed over the semiconductor substrate 1 including over the metal silicide layer 23, so as to cover the gate electrodes GE1 to GE4, and sidewalls SW1 and SW2. The insulating film 31 is constituted, for example, by silicon nitride, may be formed using a plasma CVD method or the like, and may have a thickness (the deposited film thickness) of around 20 to 50 nm.

The insulating film 31 is formed, more preferably, as either a tensile stress film or a compression stress film. When the insulating film 31 is a tensile stress film, the insulating film 31 (the tensile stress film) may increase the electron mobility in the channel regions of the n-channel type MISFETs Qn1 and Qn2, and, as the result, may increase the ON current of the n-channel type MISFETs Qn1 and Qn2. Or, when the insulating film 31 is a compression stress film, the insulating film 31 (the compression stress film) may increase the hole mobility in the channel regions of the p-channel type MISFETs Qp1 and Qp2, and, as the result, may increase the ON current of the p-channel type MISFETs Qp1 and Qp2.

When forming the tensile stress film constituted by silicon nitride as the insulating film 31, for example, a silicon nitride film is formed using silane (SiH₄), dinitrogen monoxide (N₂O) and ammonia (NH₃) by plasma CVD at a temperature of around 250 to 400° C., and, after that, it is subjected to a heat treatment at around 400 to 550° C. with the irradiation of ultraviolet rays, to form the tensile stress film constituted of the silicon nitride film. When forming the compression stress film constituted by silicon nitride as the insulating film 31, for example, a silicon nitride film is formed using silane (SiH₄), dinitrogen monoxide (N₂O) and ammonia (NH₃) by plasma CVD at a temperature of around 350 to 500° C., to form the compression stress film constituted by the silicon nitride film.

Meanwhile, in the present Example and Example 2 below, the tensile stress film means a film (an insulating film) that gives tensile stress to a semiconductor substrate for which the tensile stress film is formed, and, in regions where the tensile stress film is formed over the semiconductor substrate, tensile stress acts on (is given to, generates in) the semiconductor substrate by the tensile stress film. When the tensile stress is acted on the semiconductor substrate (the channel region in the substrate) for which the n-channel type MISFET is formed by the tensile stress film, it is possible to increase the electron mobility, or the like, and, as the result, to increase the ON current flowing in the channel of the n-channel type MISFET. The tensile stress film is occasionally referred to as a stress film of tensile. On the other hand, the compression stress film means a film (an insulating film) that gives compression stress to a semiconductor substrate for which the compression stress film is formed, and, in regions where the compression stress film is formed over the semiconductor substrate, compression stress acts on (is given to, generates in) the semiconductor substrate by the compression stress film. When the compression stress is acted on the semiconductor substrate (the channel region in the substrate) for which the p-channel type MISFET is formed by the compression stress film, it is possible to increase the hole mobility, or the like, and, as the result, to increase the ON current flowing in the channel of the p-channel type MISFET. The compression stress film is occasionally referred to as a stress film of compression.

Next, an interlayer insulating film 32 is formed as an insulating film over the whole main surface of the semiconductor substrate 1, that is, over the insulating film 31. The thickness of the interlayer insulating film 32 is thicker than that of the insulating film 31. As the material of the interlayer insulating film 32, for example, silicon oxide or the like may be employed. After forming the interlayer insulating film 32, the surface of the interlayer insulating film 32 is polished by a CMP method, or the like, to flatten the upper surface of the interlayer insulating film 32.

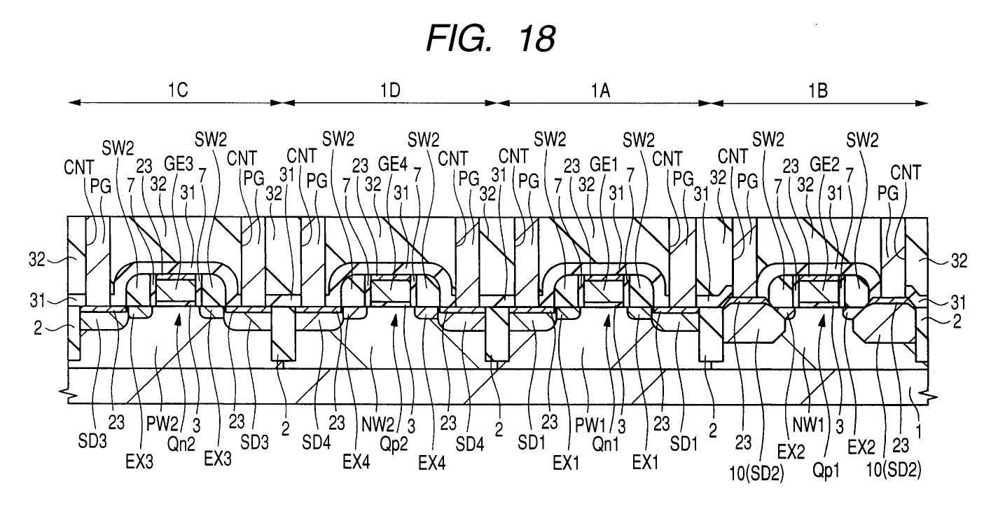

Next, using a photoresist pattern (not shown) formed over the interlayer insulating film 32 by a photolithographic method as an etching mask, the interlayer insulating film 32 and the insulating film 31 are subjected to dry etching to form, as shown in FIG. 18, a contact hole (a through hole, a hole) CNT in a laminated film constituted by the insulating film 31 and the interlayer insulating film 32.

In order to form a contact hole 22, firstly, the interlayer insulating film 32 is subjected to dry etching under such a condition that the interlayer insulating film 32 is easily etched as compared with the insulating film 31 so as to allow the insulating film 31 to function as an etching stopper film, to form the contact hole CNT in the interlayer insulating film 32. Then, under such a condition that the insulating film 31 is easily etched as compared with the interlayer insulating film 32, the insulating film 31 at the bottom portion of the contact hole CNT is subjected to dry etching and removed to form the contact hole CNT as a through hole.

Next, in the contact hole CNT, an electroconductive plug (a conductive portion for connection) PG constituted by tungsten (W) or the like is formed. In order to form the plug PG, for example, a barrier conductor film (for example, a titanium film, a titanium nitride film or a laminated film thereof) is formed over the interlayer insulating film 32 including the inside (over the bottom portion and side wall) of the contact hole CNT. Then, by forming a main conductor film constituted by a tungsten film is formed over the barrier conductor film so as to fill the contact hole CNT, and by removing an unnecessary main conductor film and barrier conductor film over the interlayer insulating film 32 by a CMP method, an etch back method or the like, the plug PG may be formed. Meanwhile, for the purpose of simplifying the drawing, in FIG. 18, the barrier conductor film and the main conductor film (a tungsten film) constituting the plug PG are shown in a united form.

In the logic nMIS region 1A, the plug PG formed in the upper portion of the source/drain region of the n-channel type MISFET Qn1 (the n⁺-type semiconductor region SD1) is contacted to the metal silicide layer 23 over the surface of the source/drain region to be connected electrically. And, in the logic pMIS region 1B, the plug PG formed in the upper portion of the source/drain region of the p-channel type MISFET Qp1 (the p⁺-type semiconductor region SD2) is contacted to the metal silicide layer 23 over the surface of the source/drain region to be connected electrically. Moreover, in the memory nMIS region 1C, the plug PG formed in the upper portion of the source/drain region of the n-channel type MISFET Qn2 (the n⁺-type semiconductor region SD3) is contacted to the metal silicide layer 23 over the source/drain region to be connected electrically. Further, in the memory pMIS region 1D, the plug PG formed in the upper portion of the source/drain region of the p-channel type MISFET Qp2 (the p⁺-type semiconductor region SD4) is contacted to the metal silicide layer, 23 over the surface of the source/drain region to be connected electrically. Although not shown schematically, the plug PG may also be formed in the upper portion of the gate electrodes GE1 to GE4.

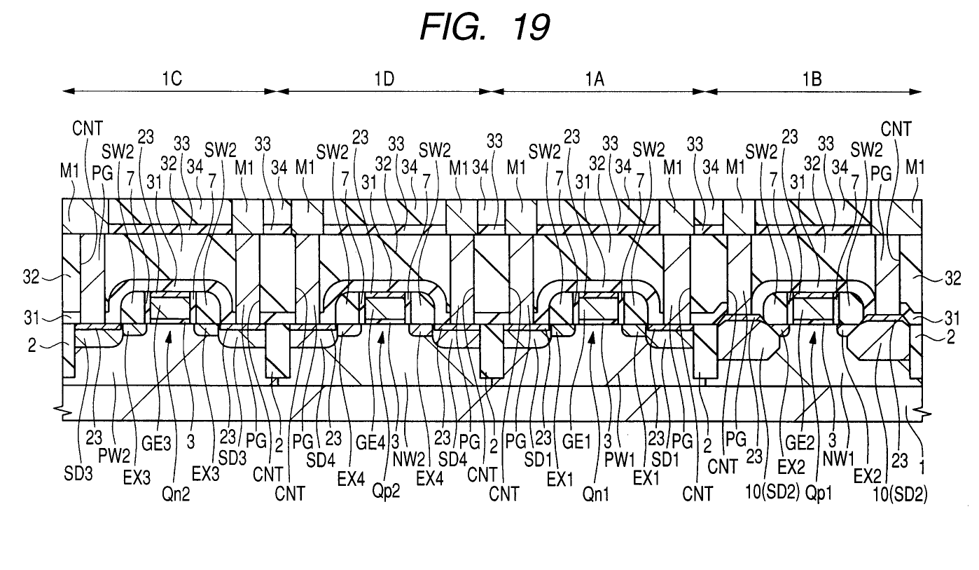

Next, as shown in FIG. 19, over the interlayer insulating film 32 in which the plug PG is embedded, a stopper insulating film (an insulating film for an etching stopper) 33 and an insulating film for forming a wiring (an interlayer insulating film) 34 are sequentially formed. The stopper insulating film 33 is a film that works as an etching stopper when the trench is processed in the insulating film 34, and a material having the etching selectivity for the insulating film 34 may be used, for example, a silicon nitride film may be set as the stopper insulating film 33, and a silicon oxide film may be set as the insulating film 34.

Next, a first layer wiring is formed by a single damascene method. Firstly, by dry etching using a photoresist pattern (not shown) as a mask, a wiring trench (in FIG. 19, the portion of the trench in which a wiring M1 is embedded) is formed in a prescribed region of the insulating film 34 and stopper insulating film 33. Then, over the main surface of the semiconductor substrate 1 (that is, over the insulating film 34 including over the bottom portion and side wall of the wiring trench), a barrier conductor film (such as a titanium nitride film, a tantalum film or a tantalum nitride film) is formed. Subsequently, over the barrier conductor film, a copper seed layer is formed by a CVD method, a sputtering method or the like, and further, over the seed layer, a copper plating film is formed using an electrolytic plating method or the like, wherein the copper plating film is embedded inside the wiring trench. After that, the copper plating film, the seed layer and the barrier metal film in other regions than the wiring trench are removed by a CMP method to form a first layer wiring M1 having copper as a main electroconductive material. Meanwhile, for simplifying the drawing, in FIG. 19, the copper plating film, the seed layer and the barrier conductor film constituting the wiring M1 are shown in a united form.

The wiring M1 is electrically connected to the source/drain regions of the n-channel type MISFETs Qn1 and Qn2 and the p-channel type MISFETs Qp1 and Qp2, the gate electrodes GE1 to GE4, and the like via the plug PG. After that, wirings subsequent to the first layer wiring are formed by a dual damascene method or the like, but the illustration and explanation thereof are omitted here. Moreover, the wiring M1 is not limited to a damascene wiring, but may be formed by patterning an electroconductive film for wiring. For example, a tungsten wiring or an aluminum wiring may also be formed. After that, the semiconductor substrate 1 is cut (divided) by dicing or the like to form semiconductor devices (corresponding to a semiconductor device SM1 described later) of respective pieces.

The semiconductor device of the Example that is manufactured as described above is a semiconductor device in which plural p-channel type MISFETs Qp1 for logic, plural n-channel type MISFETs Qn1 for logic, plural p-channel type MISFETs Qp2 for memory and plural n-channel type MISFETs Qn2 for memory are formed (mixedly mounted) over the identical semiconductor substrate 1.

The characteristics of the semiconductor device of the Example will be described.

FIG. 20 is a plan view showing an example of a semiconductor device (a semiconductor chip) SM1 of the Example that is manufactured as described above.

The semiconductor device SM1 of the Example has a memory region (a memory circuit region, a memory cell array region, an SRAM region) 41 in which a memory cell array such as an SRAM (Static Random Access Memory) is formed, and a peripheral circuit region 42 in which circuits (peripheral circuits) other than the memory are formed. The peripheral circuit region 42 includes the logic circuit region 42a in which a logic circuit is formed. According to need, the memory region 41 and the peripheral circuit region 42, or each of the peripheral circuit regions 42 are electrically connected via an internal wiring layer (the above-described wiring M1 and a wiring of the layer upper than the wiring M1) of the semiconductor device SM1. Moreover, in the peripheral portion of the main surface (the surface) of the semiconductor device SM1, plural pad electrodes (bonding pad) PD are formed along four sides of the main surface of the semiconductor device SM1. Respective pad electrodes PD are electrically connected to the memory region 41, the peripheral circuit region 42 and the like via the internal wiring layer of the semiconductor device SM1. Meanwhile, although FIG. 20 is a plan view, hatching is given to the memory region 41 and the logic circuit region 42a for easy understanding.

In the semiconductor device SM1, for respective memory regions 41 and peripheral circuit regions 42 (including the logic circuit region 42a), plural MISFETs are formed. That is, in the memory region 41, plural p-channel type MISFETs for memory and plural n-channel type MISFETs for memory are formed, and, in the logic circuit region 42a, plural p-channel type MISFETs for logic and plural n-channel type MISFETs for logic are formed.

The logic nMIS region 1A corresponds to a region in which the n-channel type MISFET is formed in the logic circuit region 42a, and the logic pMIS region 1B corresponds to a region in which the p-channel type MISFET is formed in the logic circuit region 42a. And, the memory nMIS region 1C corresponds to a region in which the n-channel type MISFET is formed in the memory region 41, and the memory pMIS region 1D corresponds to a region in which the p-channel type MISFET is formed in the memory region 41. Accordingly, in the logic circuit region 42a, plural n-channel type MISFETs Qn1 for logic and plural p-channel type MISFETs Qp1 for logic are formed, and, in the memory region 41, plural n-channel type MISFETs Qn2 for memory and plural p-channel type MISFETs Qp2 for memory are formed.

The p-channel type MISFET Qp1 is a p-channel type field effect transistor for logic, and has the source/drain region constituted by the silicon-germanium (the silicon-germanium region 10) (the p⁺-type semiconductor region SD2). The silicon-germanium region 10 may act (apply) compression stress on a channel region (a substrate region just under the gate electrode GE2 (the n-type well NW1)) of the p-channel type MISFET Qp1, which may increase the hole mobility (the hole mobility in the channel region) (the technique is referred to as a SiGe strain technique). This may increase the ON current flowing the channel of the p-channel type MISFET Qp1, and may increase the speed of the operation. That the silicon-germanium region 10 acts compression stress on the channel region is mainly caused by that the lattice constant of silicon-germanium (the silicon-germanium region 10) is larger than the lattice constant of silicon (the semiconductor substrate 1 including the n-type well NW1).

On the other hand, the n-channel type MISFET Qn1 is an n-channel type field effect transistor for logic, and has a source/drain region constituted by silicon (the n⁺-type semiconductor region SD1). And, the p-channel type MISFET Qp2 is a p-channel type field effect transistor for memory, and has a source/drain region constituted by silicon (p⁺-type semiconductor region SD4). Moreover, the n-channel type MISFET Qn2 is an n-channel type field effect transistor for memory, and has a source/drain region constituted by silicon (the n⁺-type semiconductor region SD3). That is, the p-channel type MISFET Qp1 is a MISFET to which the SiGe strain technique is applied, and the n-channel type MISFETs Qn1 and Qn2 and the p-channel type MISFET Qp2 are MISFETs to which the SiGe strain technique is not applied.

The source/drain region (the p⁺-type semiconductor region SD2) of the p-channel type MISFET Qp1 that is constituted by silicon-germanium (the silicon-germanium region 10) is formed, as described above, from silicon-germanium (the silicon-germanium region 10) epitaxially grown in the trench 9 provided in the semiconductor substrate 1. On the other hand, source/drain regions (the n⁺-type semiconductor regions SD1 and SD3, and the p⁺-type semiconductor region SD4) of the n-channel type MISFETs Qn1 and Qn2, and the p-channel type MISFET Qp2, which are constituted by silicon, are formed, as described above, by introducing an impurity (implanting an ion) into the semiconductor substrate 1.

When the SiGe strain technique as described above is used, the use of a <110> channel having high sensitivity of mobility (hole mobility) relative to the strain is preferable. That is, the <110> direction has a larger amount of variation in the hole mobility when a channel region is strained by compression stress as compared with other directions, and, therefore, in order to achieve the improvement of the mobility by the SiGe strain technique and the improvement of the ON current caused by it, the use of the <110> channel is preferable. Here, the <110> channel corresponds to that the gate length direction of the channel region is the <110> direction of crystalline Si (that is, the <110> direction of silicon constituting the semiconductor substrate 1 including the well region). By setting the channel region of the p-channel type MISFET, for which the SiGe strain technique is used such as the p-channel type MISFET Qp1, to be the <110> channel, it is possible to enhance the improving effect of the hole mobility, and to enhance the improving effect of the ON current.

On the other hand, it is preferable not to apply the above-described SiGe strain technique to the n-channel type MISFET. This is because the carrier of the n-channel type MISFET is electrons, and the mobility of electrons being the carrier lowers by contrast when the compression stress acts on the channel region of the n-channel type MISFET. Therefore, to the n-channel type MISFETs Qn1 and Qn2, the above-described SiGe strain technique is not applied, and these MISFETs have the source/drain region constituted by silicon (the n⁺-type semiconductor regions SD1 and SD3).

As described above, by applying the SiGe strain technique to the p-channel type MISFET and by not applying it to the n-channel type MISFET, it is possible to improve the hole mobility in the channel region of the p-channel type MISFET without lowering the electron mobility in the channel region of the n-channel type MISFET. Accordingly, it becomes possible to improve the ON current of the p-channel type MISFET without lowering the ON current of the n-channel type MISFET.

In the above-described SiGe strain technique, however, a crystal defect generates easily near the interface of SiGe/Si when the silicon-germanium region is epitaxially grown in the trench of the Si substrate, and the crystal defect may cause the increase in the leak current of the MISFET. Accordingly, the p-channel type MISFET to which the SiGe strain technique is applied may improve the hole mobility as compared with the p-channel type MISFET to which no SiGe strain technique is applied, but, by contrast, there occurs the concern of the increase in the leak current.

Consequently, when plural p-channel type MISFETs and plural n-channel type MISFETs are mixedly mounted in the identical semiconductor substrate (the semiconductor chip), if the SiGe strain technique is uniformly applied to all p-channel type MISFETs, there is such a concern as the lowering of the performance of the semiconductor device caused by the increase in the leak current in all the p-channel type MISFETs.

In the Example, therefore, when plural p-channel type MISFETs and plural n-channel type MISFETs are mixedly mounted in the identical semiconductor substrate (the semiconductor chip), the SiGe strain technique is not uniformly applied to all the p-channel type MISFETs, but the SiGe strain technique is properly used for plural p-channel type MISFETs so as to apply the technique to some of them and not to apply it to the other. That is, the SiGe strain technique is applied to p-channel type MISFETs in which priority is given to the improvement of the hole mobility (that is, the increase in the ON current and the improvement of the operation speed) rather than the possibility of the increase in the leak current, but, on the other hand, the SiGe strain technique is not applied to p-channel type MISFETs in which the increase in the leak current is to be suppressed as far as possible. Moreover, it is designed so that the SiGe strain technique is not applied to all the n-channel type MISFETs. This makes it possible to design respective MISFETs so as to correspond to properties required for respective MISFETs, and to improve the performance of the entire semiconductor device.

In the Example, semiconductor devices are manufactured under such design concept, and, specifically, the application or non-application of the SiGe strain technique is properly used as follows.

In the memory region 41 of the semiconductor device SM1, plural p-channel type MISFETs and plural n-channel type MISFETs are formed, but, to all the p-channel type MISFETs and n-channel type MISFETs formed in the memory region 41, the SiGe strain technique is not applied. This is because the need for low power consumption is particularly high in such a memory (a memory cell) as SRAM as compared with other circuits (circuit elements), and it is desirable to reduce the leak current as far as possible. In the Example, since the SiGe strain technique is not applied to all the p-channel type MISFETs and n-channel type MISFETs formed in the memory region 41, it is possible to suppress the leak current and to make the standby current small, and to achieve the low power consumption of the memory.

Accordingly, in the memory region 41, the plural n-channel type MISFETs Qn2 and the plural p-channel type MISFETs Qp2 are formed, but such a MISFET as the p-channel type MISFET Qp1 formed in the logic pMIS region 1B, to which the SiGe strain technique is applied, is not formed in the memory region 41.

On the other hand, in the Example, in the logic circuit region 42a of the semiconductor device SM1, plural p-channel type MISFETs and plural n-channel type MISFETs are formed. And, to all the n-channel type MISFETs formed in the logic circuit region 42a, the SiGe strain technique is not applied, but, to at least a part of the p-channel type MISFETs among the plural p-channel type MISFETs formed in the logic circuit region 42a, the SiGe strain technique is applied. This is because the high speed operation is highly required for a logic element (a logic circuit) and the improvement of the carrier mobility as far as possible is desirable. In the Example, by applying the SiGe strain technique to at least a part of p-channel type MISFETs among plural p-channel type MISFETs formed in the logic circuit region 42a, it is possible to make the operation speed of the logic elements (logic circuits), to which the p-channel type MISFET is applied, high, and to improve the performance of the semiconductor device.

Accordingly, at least a part of p-channel type MISFETs among the plural p-channel type MISFETs formed in the logic circuit region 42a have the same constitution as the p-channel type MISFET Qp1 in the logic pMIS region 1B to which the SiGe strain technique is applied. And, since the SiGe strain technique is not applied to the plural n-channel type MISFETs formed in the logic circuit region 42a, these MISFETs have the same constitution as the n-channel type MISFET Qn1 formed in the logic nMIS region 1A.

Further, in the Example, although plural n-channel type MISFETs are formed in the semiconductor device SM1, to all the n-channel type MISFETs formed in the semiconductor device SM1, the SiGe strain technique is not applied. This makes it possible to prevent the lowering of the electron mobility in the channel region of the n-channel type MISFET formed in the semiconductor device SM1, and to prevent the lowering of the ON current and operation speed of the n-channel type MISFET.

Accordingly, regarding the plural n-channel type MISFETs formed for the semiconductor device SM1, since the SiGe strain technique is not applied to all the n-channel type MISFETs, they have the same constitution as the n-channel type MISFET Qn1 formed in the logic nMIS region 1A, or the n-channel type MISFET Qn2 formed in the memory nMIS region 1C.

As described above, in the semiconductor device SM1 of the Example, plural p-channel type MISFETs for logic, plural n-channel type MISFETs for logic, plural p-channel type MISFETs for memory, and plural n-channel type MISFETs for memory are mixedly mounted over the semiconductor substrate 1 constituting the semiconductor device SM1. And, at least a part of p-channel type MISFETs for logic (the p-channel type MISFET Qp1) formed over the semiconductor substrate 1 are applied with the SiGe strain technique to have the source/drain region constituted by silicon-germanium (the silicon-germanium region 10). All of the n-channel type MISFETs for logic, p-channel type MISFETs for memory, and n-channel type MISFETs for memory formed over the semiconductor substrate 1, however, are not applied with the SiGe strain technique, and each of them has the source/drain region constituted by silicon.

As described above, in the Example, when p-channel type MISFETs for logic in the logic circuit region 42a and p-channel type MISFETs for memory in the memory region 41 are mixedly mounted over the semiconductor substrate 1 (the semiconductor device SM1), it is designed so that the p-channel type MISFET for logic in the logic circuit region 42a is selectively applied with the SiGe strain technique, and that the p-channel type MISFET for memory in the memory region 41 is not applied with the SiGe strain technique. That is, it is intended so that the SiGe strain technique is applied to the p-channel type MISFET for logic in the logic circuit region 42a, in which priority is given to the improvement of the hole mobility (that is, the improvement of the increase in the ON current or of the operation speed) rather than the possibility of the increase in the leak current, and that the SiGe strain technique is not applied to the p-channel type MISFET for memory in the memory region 41, in which the increase in the leak current is to be suppressed as far as possible in order to lower the power consumption. This makes it possible to actualize the high speed operation of the logic element (the logic circuit) in the logic circuit region 42a in which priority is given to high speed operation, and the reduction of the power consumption of the memory circuit in the memory region 41 in which priority is given to the low power consumption, and to design respective MISFETs corresponding to the property required according to the kind of respective circuits to improve the performance of the whole semiconductor device.

Further, when all the p-channel type MISFETs for logic formed over the semiconductor substrate 1 are applied with the SiGe strain technique to lead to the constitution having the source/drain region constituted by silicon-germanium (the same constitution as that of the above p-channel type MISFET Qp1), it is possible to achieve the improvement of the hole mobility (that is, the increase in the ON current and improvement of the operation speed) for all the p-channel type MISFETs for logic. On this occasion, the improving, effect of the operation speed of the logic element (the logic circuit) may be made maximum.

On the other hand, in plural p-channel type MISFETs for logic formed over the semiconductor substrate 1, there is such a case where the p-channel type MISFET for logic in which priority is given to the high operation speed and the p-channel type MISFET for logic in which priority is given to the suppression of the leak current coexist. In this case, the SiGe strain technique is applied to only a part of p-channel type MISFETs for logic (p-channel type MISFETs for logic in which priority is given to the high operation speed) among plural p-channel type MISFETs for logic formed over the semiconductor substrate 1 to lead them to the constitution having the source/drain region constituted by silicon-germanium (the same constitution as that of the p-channel type MISFET Qp1). And, the SiGe strain technique is not applied to remaining p-channel type MISFETs for logic to lead them to the constitution having the source/drain region constituted by silicon (the same constitution as that of the p-channel type MISFET Qp2). This makes it possible to improve the operation speed of the logic element (the logic circuit) while suppressing the leak current of the logic element (the logic circuit). Among p-channel type MISFETs for logic, one for which high operation speed is required in particular is the p-channel type MISFET for logic used for an arithmetic circuit. Consequently, even when the SiGe strain technique is applied to only a part of p-channel type MISFETs for logic among plural p-channel type MISFETs for logic formed over the semiconductor substrate 1, the p-channel type MISFET for logic used for an arithmetic circuit is preferably applied with the SiGe strain technique to give a constitution having the source/drain region constituted by silicon-germanium (the same constitution as that of the p-channel type MISFET Qp1).

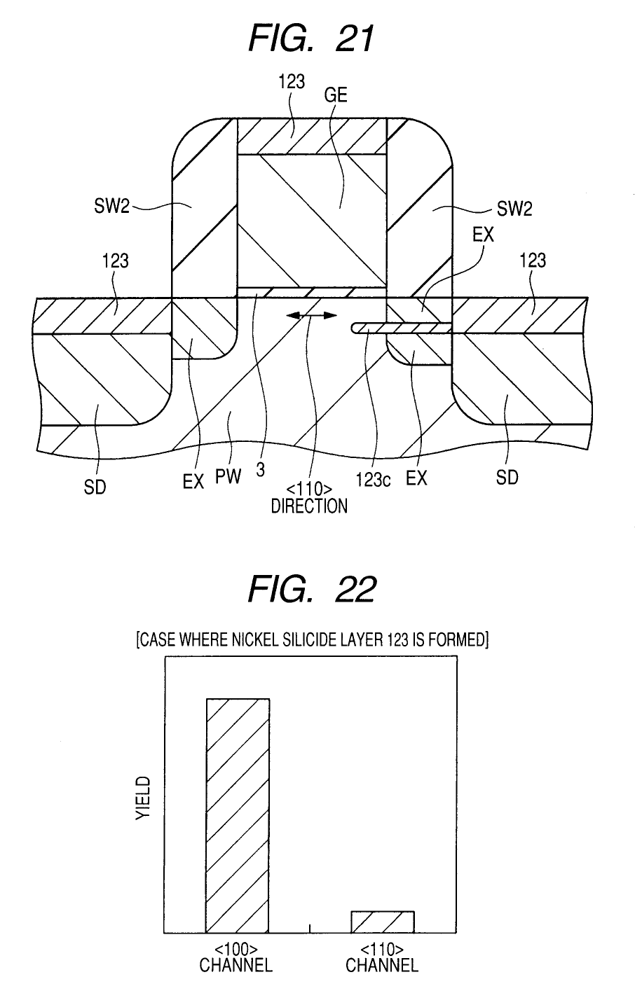

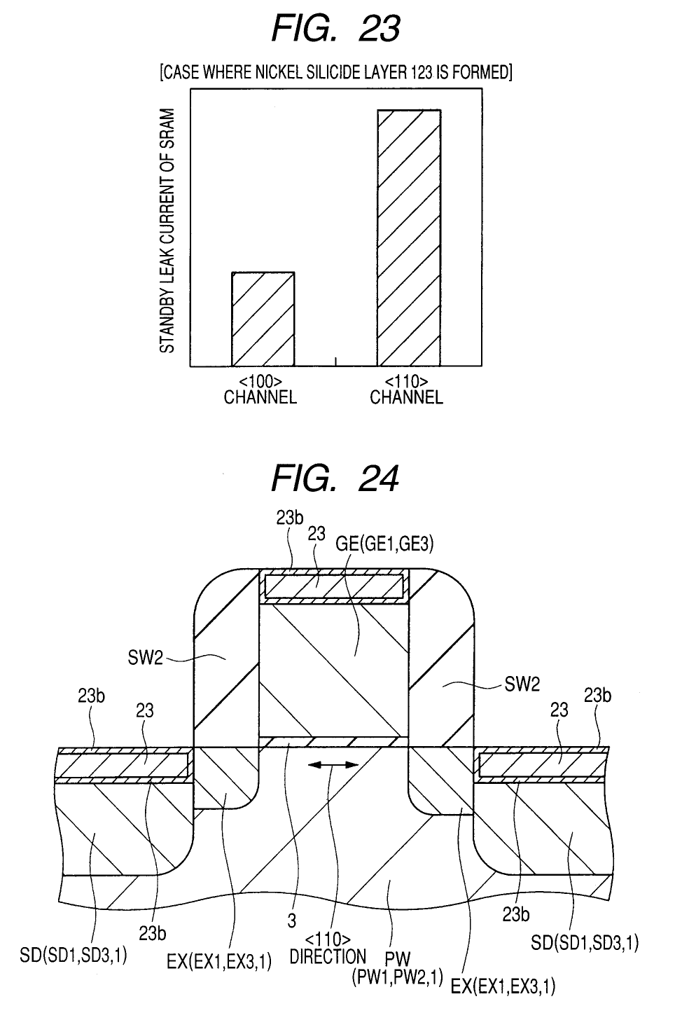

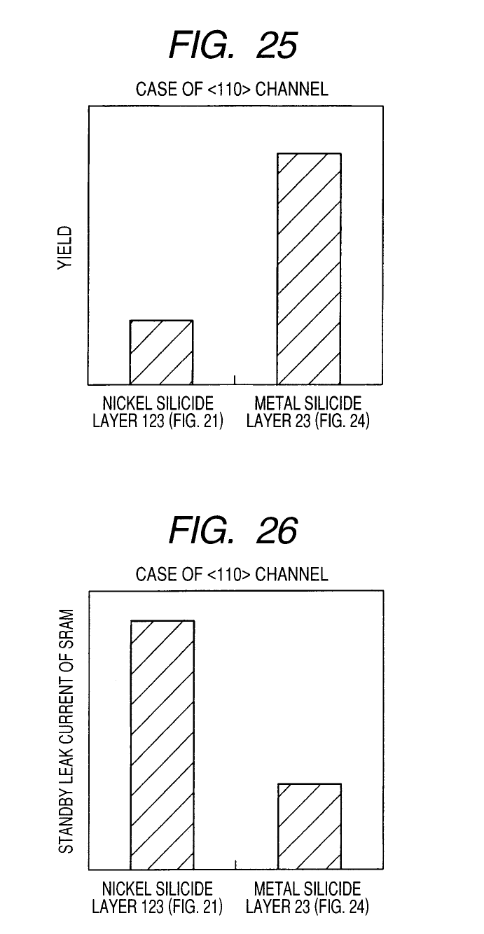

FIG. 21 is an explanatory drawing of an abnormal growth of a nickel silicide layer 123 formed over the source/drain region SD.

FIG. 21 shows a cross-sectional view of the essential part of the n-channel type MISFET at the stage in which the nickel silicide layer 123 is formed by a salicide process (a process stage corresponding to that in FIG. 16). In FIG. 21, a gate electrode GE corresponding to the gate electrodes GE1 and GE3 of the Example is formed over a p-type well PW corresponding to the p-type wells PW1 and PW2 of the Example via the gate insulating film 3, and, over the side wall of the gate electrode GE, the sidewall SW2 is formed. And, in the p-type well PW, an extension region EX corresponding to the n⁻-type semiconductor regions EX1 and EX3 of the Example, and a source/drain region SD corresponding to the n⁺-type semiconductor regions SD1 and SD3 of the Example are formed, and, over the source/drain region SD, the nickel silicide layer 123 is formed by the salicide process.

As the result of careful check of the present inventor on the semiconductor device in which the n-channel type MISFET is formed, it was known that, when the nickel silicide layer 123 is formed by the salicide process over the source/drain region SD, as shown in FIG. 21, NiSi₂ (nickel disilicide) abnormally grows easily from the nickel silicide layer 123 of a NiSi phase to the channel region. In FIG. 21, a region in which NiSi₂ abnormally grows easily is schematically shown as a NiSi₂ abnormal growth region 123c. The occurrence of such NiSi₂ abnormal growth region 123c was confirmed by the experiment (such as observation and composition analysis of the cross-section of the semiconductor device, and the like) of the inventor. Moreover, it was also known that the abnormal growth of NiSi₂ from the nickel silicide layer 123 to the channel region leads to the increase in the leak current between the source and drain of the MISFET. The NiSi₂ abnormal growth region 123c is a phenomenon that significantly occurs in the n-channel type MISFET as compared with the p-channel type MISFET.

Moreover, as the result of further detailed check of the inventor on the NiSi₂ abnormal growth region 123c, it was known that the NiSi₂ abnormal growth region 123c easily grows from the nickel silicide layer 123 to the <110> direction of the substrate Si. That is, when the <110> channel is used as the channel region, NiSi₂ abnormally grows in particular from the nickel silicide layer 123 to the channel region as compared with a case where the channel direction (the gate length direction) is not the <110> direction. Therefore, the use of the <110> channel as the channel region of the n-channel type MISFET may lead to the increase in the leak current caused by the NiSi₂ abnormal growth region 123c.

FIG. 22 is a graph showing the yield when the channel region of the n-channel type MISFET is a <100> channel and when it is the <110> channel, when the nickel silicide layer 123 is formed by the salicide process over the source/drain region SD of the n-channel type MISFET as shown in FIG. 21. FIG. 23 is a graph showing the standby leak current (the leak current at waiting) when the channel region of the n-channel type MISFET constituting an SRAM is the <100> channel and when it is the <110> channel, when the nickel silicide layer 123 is formed by the salicide process over the source/drain region SD of the n-channel type MISFET constituting the SRAM. The vertical axis of graphs in FIGS. 22 and 23 has an arbitrary unit.

As described above, when the channel region of the n-channel type MISFET is the <110> channel, the NiSi₂ abnormal growth region 123c occurs easily as compared with when it is the <100> channel, and, due to the NiSi₂ abnormal growth region 123c, in the case of the <110> channel, the yield lowers as compared with the case of the <100> channel as shown in FIG. 22, and the leak current increases as shown in FIG. 23.

In order to prevent the increase in the leak current caused by the NiSi₂ abnormal growth region 123c, it is also considered not to use the <110> channel for the n-channel type MISFET. In the Example, however, the p-channel type MISFET Qp1, to which the SiGe strain technique is applied, is formed in the logic circuit region 42a, and, in the channel region of the p-channel type MISFET Qp1, the use of the <110> channel is preferable in order to enhance the improving effect of the hole mobility. Consequently, each of the p-channel type MISFETs Qp1 formed in the logic circuit region 42a preferably has the <110> channel.

Consequently, there is such a request that the channel region of the n-channel type MISFET Qn1 formed in the logic circuit region 42a uses the <110> channel from the standpoint of easiness of layout among MISFETs and reduction of the whole area of the semiconductor device SM1 as far as possible. From the same standpoint, there is such a request that the channel region of the n-channel type MISFET Qn2 formed in the memory region 41 also uses the <110> channel. When channel regions of the n-channel type MISFET Qn1 formed in the logic circuit region 42a and of the n-channel type MISFET Qn2 formed in the memory region 41 also use the <110> channel, however, there is a concern of the occurrence of the NiSi₂ abnormal growth region 123c when the nickel silicide layer 123 is formed by the salicide process over the source/drain region SD.

The inventor examined, therefore, what kind of metal silicide may be used as the metal silicide layer to be formed over the source/drain region of the n-channel type MISFET in order to prevent the occurrence of such an abnormal growth portion as the NiSi₂ abnormal growth region 123c even when the <110> channel is used. As the result, it was known that the use of the metal silicide layer 23 instead of the nickel silicide layer 123 makes it possible to prevent the occurrence of such an abnormal growth portion as the NiSi₂ abnormal growth region 123c from the metal silicide layer 23 to the channel region, even when the <110> channel is used in the channel region of the n-channel type MISFET.

FIG. 24 is an explanatory drawing (the essential part plan view) of the n-channel type MISFET formed in the semiconductor device SM1 of the Example, which corresponds to the n-channel type MISFETs Qn1 and Qn2. In FIG. 24, over the p-type well PW corresponding to the p-type wells PW1 and PW2, the gate electrode GE corresponding to the gate electrodes GE1 and GE3 is formed via the gate insulating film 3, and, over the side wall of the gate electrode GE, the sidewall SW2 is formed. And, in the p-type well PW, the extension region EX corresponding to the n⁻-type semiconductor regions EX1 and EX3, and the source/drain region SD corresponding to the n⁺-type semiconductor regions SD1 and SD3 are formed, and, over the source/drain region SD, the metal silicide layer 23 is formed. Regarding the aforementioned portions of the constitution and the method of manufacturing the metal silicide layer 23, repeating descriptions are omitted as far as possible.

Although the NiSi₂ abnormal growth region 123c occurs easily when the nickel silicide layer 123 is formed, the occurrence of the abnormal growth portion from the metal silicide layer 23 to the channel region may be prevented by further incorporating at least one kind of element selected from the group having Pt, Pd, Hf, V, Al, Er, Yb and Co (that is, the metal element Me), preferably Pt, in addition to Ni into the metal silicide layer 23, as the Example.

This is caused by the segregation of the metal element Me (more preferably Pt) added to the metal silicide layer 23 near the interface of the metal silicide layer 23 and the semiconductor substrate 1 constituted by silicon, as schematically shown in FIG. 24. Meanwhile, since the p-type well PW, the extension region EX and the source/drain region SD are formed by introducing an impurity (implanting an ion) into the semiconductor substrate 1, it may be considered as a part of the semiconductor substrate 1 constituted by silicon (a silicone substrate region). FIG. 24 schematically shows a region in which the metal element Me (at least one kind of element selected from the group having Pt, Pd, Hf, V, Al, Er, Yb and Co, more preferably Pt) segregates as a segregation region 23b. Meanwhile, the segregation region 23b was checked by RBS (Rutherford backscattering analysis).

When the segregation region 23b, in which the metal element Me exists (segregates) in a higher concentration than the concentration of the metal element Me in the metal silicide layer 23, lies near the interface of the metal silicide layer 23 and the silicon substrate region (the semiconductor substrate 1), the segregation region 23b works as a barrier to make it possible to prevent the abnormal growth of Ni_{1-y}Me_{y}Si₂ from the metal silicide layer 23 to the channel region (which corresponds to the NiSi₂ abnormal growth region 123c). Therefore, in the Example, the metal silicide layer 23 contains the metal element Me that easily forms the segregation region 23b near the interface of the metal silicide layer 23 and the silicon substrate region. In order to obtain the effect of preventing the abnormal growth of Ni_{1-y}Me_{y}Si₂ based on the formation of the segregation region 23b, as the metal element Me that is incorporated into the metal silicide layer 23 in addition to Ni, at least one kind of element selected from the group having Pt, Pd, Hf, V, Al, Er, Yb and Co is preferable, and Pt is most preferable.

In order to prevent the abnormal growth, it is important to form the segregation region 23b near the interface of the metal silicide layer 23 and the silicon substrate region (semiconductor substrate 1), and, actually, as schematically shown in FIG. 24, the segregation region 23b may be formed not only at the interface of the metal silicide layer 23 and the silicon substrate region (semiconductor substrate 1), but also over the whole outer surface of the metal silicide layer 23 (the upper, lower and side surfaces of the metal silicide layer 23). Even in this case, too, when the segregation region 23b is formed at least near the interface of the metal silicide layer 23 and the silicon substrate region (semiconductor substrate 1), the effect of preventing the abnormal growth may be obtained.

Further, the NiSi₂ abnormal growth region 123c hardly occurs in the p-channel type MISFET as compared with the n-channel type MISFET, and, therefore, the occurrence of the segregation region 23b at least in the metal silicide layer 23 formed over the source/drain region of the n-channel type MISFETs Qn1 and Qn2 (the n⁺-type semiconductor regions SD1 and SD3), may give the effect of preventing the abnormal growth.

Actually, however, the metal silicide layer 23 of the p-channel type MISFETs Qp1 and Qp2 is also formed by the same process as that for the metal silicide layer 23 of the n-channel type MISFETs Qn1 and Qn2. Consequently, the segregation region 23b is formed near the interface of the metal silicide layer 23 and the silicon substrate region in the metal silicide layer 23 formed over the source/drain region of the p-channel type MISFETs Qp1 and Qp2 (the p⁺-type semiconductor regions SD2 and SD4), too, in the same manner as that in the metal silicide layer 23 formed over the source/drain region of the n-channel type MISFETs Qn1 and Qn2 (the n⁺-type semiconductor regions SD1 and SD3). Moreover, in the metal silicide layer 23 formed over the gate electrodes GE1 to GE4, too, the segregation region 23b may be formed over the whole outer surface of the metal silicide layer 23 (the upper, lower and side surfaces of the metal silicide layer 23).

When forming the metal silicide layer 23 by the salicide process, the metal silicide layer 23 is preferably formed under a manufacturing condition that allows the segregation region 23b to be formed as far as possible near the interface of the metal silicide layer 23 and the silicon substrate region. From this standpoint, the above-described conditions of the first and second heat treatments are set.

That is, the first heat treatment is performed under a heat treatment condition that allows the metal element Me to segregate easily near the interface of the metal silicide layer 23a and the silicon substrate region at the stage of forming the metal silicide layer 23a by performing the first heat treatment. When the first heat treatment is excessive, the metal element Me does not segregate but sufficiently diffuses into the metal silicide layer 23a, and, therefore, the heat treatment temperature and heat treatment time of the first heat treatment are preferably controlled to lead to low-temperature short-time annealing, so as not to give an excessive first heat treatment. This leads to the segregation of the metal element Me near the interface of the metal silicide layer 23a and the silicon substrate region (semiconductor substrate 1) at the stage of performing the first heat treatment and forming the metal silicide layer 23a. The preferable range and the like of the heat treatment temperature and heat treatment time of the first heat treatment are described above, and the explanation thereof is omitted here.

Moreover, after the stage of performing the first heat treatment so that the metal element Me segregates near the interface of the metal silicide layer 23a and the silicon substrate region, the second heat treatment is performed under a heat treatment condition so that the state, in which the metal element Me segregates near the interface of the metal silicide layer 23 and the silicon substrate region, is easily maintained at the stage of performing the second heat treatment, too. When the second heat treatment is excessive, since the metal element Me does not segregate, but it sufficiently diffuses into the metal silicide layer 23, the heat treatment temperature and heat treatment time of the second heat treatment are preferably controlled so as not to give an excessive second heat treatment. This leads to the segregation of the metal element Me near the interface of the metal silicide layer 23 and the silicon substrate region (the semiconductor substrate 1) at the stage of forming the metal silicide layer 23 by performing the second heat treatment. The preferable range and the like of the heat treatment temperature and heat treatment time of the second heat treatment are described above, and the explanation thereof is omitted here.

As described above, in the Example, the abnormal growth of Ni_{1-y}Me_{y}Si₂ from the metal silicide layer 23 to the channel region may be prevented by incorporating the metal element Me, which forms easily the segregation region 23b near the interface of the metal silicide layer 23 and the silicon substrate region, into the metal silicide layer 23, and, more preferably, by forming the metal silicide layer 23 under a manufacturing condition that allows the segregation region 23b to be formed easily. This may reduce the leak current of the MISFET, and improve the performance and reliability of the semiconductor device.

Consequently, in the Example, since the abnormal growth of Ni_{1-y}Me_{y}Si₂ from the metal silicide layer 23 to the channel region may be prevented even when the <110> channel is used, the n-channel type MISFET having the <110> channel may be formed in the semiconductor device SM1 while preventing the lowering of the leak current. Accordingly, since it is possible to provide the n-channel type MISFETs Qn1 and Qn2 having the <110> channel in the logic circuit region 42a and the memory region 41 while preventing the lowering of the leak current, the layout among MISFETs is easily designed, and the area reduction of the whole semiconductor device SM1 may be achieved. Consequently, the application of the Example brings about a large effect when the n-channel type MISFET Qn1 having the <110> channel is formed in the logic circuit region 42a, or when the n-channel type MISFET Qn2 having the <110> channel is formed in the memory region 41.

FIG. 25 is a graph showing the yield when the nickel silicide layer 123 is formed by the salicide process as shown in FIG. 21 over the source/drain region SD of the n-channel type MISFET having the <110> channel, and when the metal silicide layer 23 is formed as shown in FIG. 22 (the Example). FIG. 26 is a graph showing the standby leak current (the leak current at waiting) when the nickel silicide layer 123 is formed by the salicide process as in FIG. 21 over the source/drain region SD of the n-channel type MISFET constituting SRAM and having the <110> channel, and when the metal silicide layer 23 is formed as in FIG. 22 (the Example). The vertical axis of graphs in FIGS. 25 and 26 has an arbitrary unit.

As described above, since the formation of the metal silicide layer 23 according to the Example over the source/drain region SD of the n-channel type MISFET makes it possible to prevent such abnormal growth as the NiSi₂ abnormal growth region 123c even when the <110> channel is used as compared with a case where the nickel silicide layer 123 is formed, it is possible to improve the yield as shown in FIG. 25, and to reduce the leak current as shown in FIG. 26.

### Example 2

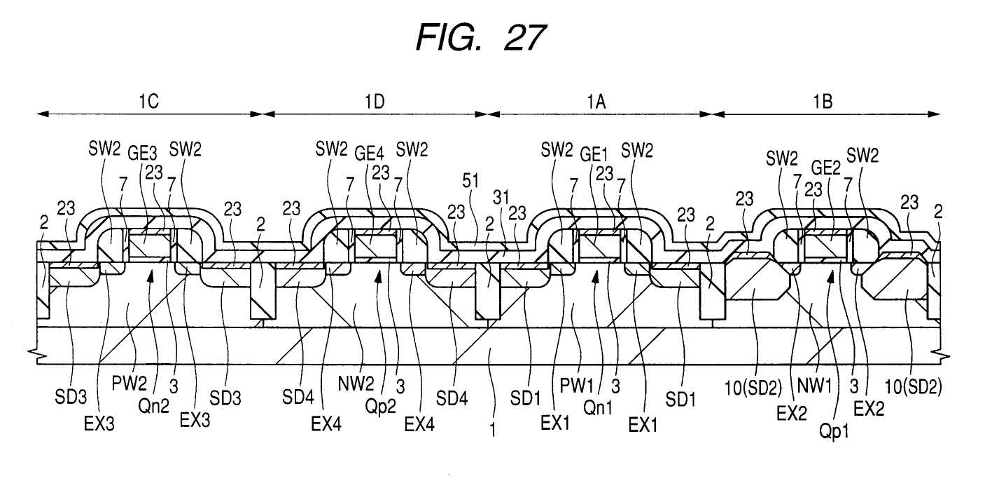

FIGS. 27 to 32 are a cross-sectional view of the essential part in the manufacturing process of a semiconductor device of the present Example.

The process of manufacturing a semiconductor device of the Example is the same as that of the above-described Example 1 until the formation of the metal silicide layer 23, and the description thereof is omitted here.

In the Example, after obtaining the structure (the structure in which the metal silicide layer 23 is formed) in FIG. 16 in the same manner as in the above-described Example, as shown in FIG. 27, the insulating film 31 is formed over the whole main surface of the semiconductor substrate 1, that is, over the main surface of the semiconductor substrate 1 including the logic nMIS region 1A, the logic pMIS region 1B, the memory nMIS region 1C and the memory pMIS region 1D. The insulating film 31 is formed over the semiconductor substrate 1 including over the metal silicide layer 23 so as to cover the gate electrodes GE1 to GE4, and the sidewalls SW1 and SW2.

In the Example, the insulating film 31 is either the tensile stress film or the compression stress film, and, hereinafter, a case where the insulating film 31 is the compression stress film will be mainly described.

The insulating film 31 is constituted, for example, by silicon nitride, and may be formed using a plasma CVD method or the like. The thickness (the deposited film thickness) thereof may be set to be around 20 to 50 nm. When the compression stress film constituted by silicon nitride is formed as the insulating film 31, for example, silane (SiH₄), dinitrogen monoxide (N₂O) and ammonia (NH₃) may be used for forming a silicon nitride film by plasma CVD at a temperature of around 350 to 500° C. to form the compression stress film constituted by the silicon nitride film.

After forming the insulating film 31, an insulating film 51 is formed over the whole main surface of the semiconductor substrate 1 including the logic nMIS region 1A, the logic pMIS region 1B, the memory nMIS region 1C and the memory pMIS region 1D, that is, over the insulating film 31. The most appropriate film as the insulating film 31 is a silicon oxide film represented by a SiO₂ film (for example, an NSG (non-doped silicate glass) film). But, it is not limited to the SiO₂ film only when it may give the selectivity of etching relative to an insulating film 52 to be formed later. In order to give the selectivity of etching between the insulating film 52 to be formed later and the insulating film 51, the insulating film 51 is necessarily formed from a material different from that of the insulating film 52. For example, when a silicon nitride film is used as the insulating film 52 to be formed later, a silicon oxide film is favorable as the insulating film 51, and, in addition, a silicon carbide film, a silicon nitride carbide film or a silicon nitride oxide film may be used as the insulating film 51. The thickness (formed film thickness) of the insulating film 51 is preferably around 6 to 20 nm.

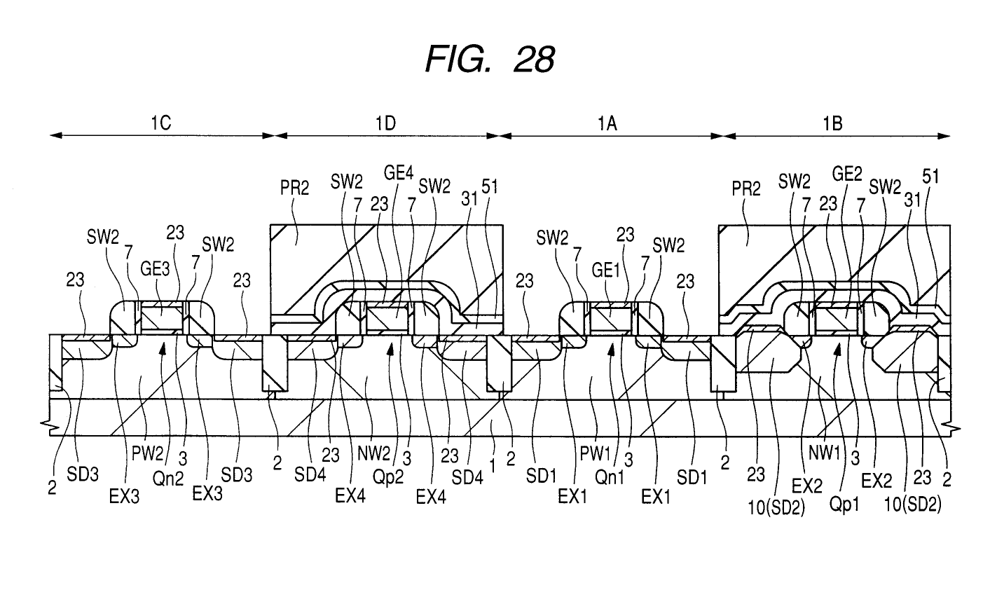

Next, as shown in FIG. 28, a photoresist film PR2, which covers the logic pMIS region 1B and the memory pMIS region 1D and exposes the logic nMIS region 1A and the memory nMIS region 1C, is formed over the insulating film 51 using a photolithographic method. Then, using the photoresist film PR2 as an etching mask, the insulating film 51 and the insulating film 31 under the film 51 lying in the logic nMIS region 1A and the memory nMIS region 1C are dry-etched and removed. In the dry etching process in FIG. 28, since the photoresist film PR2 functions as the etching mask, the insulating film 51 and the insulating film 31 under the film 51 in the logic pMIS region 1B and the memory pMIS region 1D are not etched but left. After that, the photoresist film PR2 is removed by ashing or the like.

Under a boundary line (boundary) between a region to be dry-etched (a region in which the insulating film 31 is to be etched and removed) and a region not to be dry-etched (a region in which the insulating film 31 is not etched and left), when the insulating film 51 and the insulating film 31 are dry-etched in the dry etching process in FIG. 28, the element isolation region 2 preferably lies to protect the metal silicide layer 23.

Meanwhile, when the insulating film 31 is the tensile stress film instead of the compression stress film, it may be designed so that the photoresist film PR2 covers the logic nMIS region 1A and the memory nMIS region 1C and exposes the logic pMIS region 1B and the memory pMIS region 1D, and that the photoresist film PR2 is used as an etching mask to dry-etch and remove the insulating film 51 and the insulating film 31 in the logic pMIS region 1B and the memory pMIS region 1D.

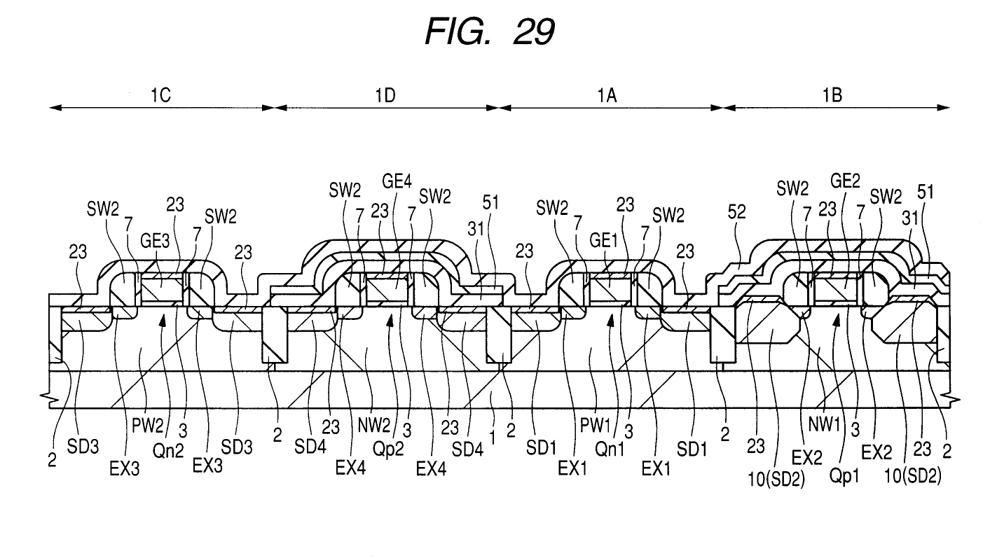

Next, as shown in FIG. 29, the insulating film 52 is formed over the whole main surface of the semiconductor substrate 1, that is, over the whole main surface of the semiconductor substrate 1 including the logic nMIS region 1A, the logic pMIS region 1B, the memory nMIS region 1C and the memory pMIS region 1D. When the insulating film 31 is the compression stress film, the insulating film 52 is set to be the tensile stress film. The insulating film 52 is formed, in the logic nMIS region 1A and the memory nMIS region 1C, over the semiconductor substrate 1 including over the metal silicide layer 23 so as to cover the gate electrodes GE1 and GE3 and the sidewall SW2 over the side wall thereof, and, in the logic pMIS region 1B and the memory pMIS region 1D, it is formed over the insulating film 51 because there lies a laminated film of the insulating film 51 and the insulating film 31 under the film 51.

The insulating film 52 may, for example, be constituted by silicon nitride, be formed using a plasma CVD method or the like, and have a thickness (the deposited film thickness) of around 20 to 50 nm. When the tensile stress film constituted by silicon nitride is to be formed as the insulating film 52, for example, it is possible to form the tensile stress film constituted by the silicon nitride film by forming a silicon nitride film using silane (SiH₄), dinitrogen monoxide (N₂O) and ammonia (NH₃) by a plasma CVD method at a temperature of around 250 to 400° C., and, after that, subjecting it to a heat treatment at around 400 to 550° C. with the irradiation of ultraviolet rays.

Meanwhile, when the insulating film 31 is the tensile stress film instead of the compression stress film, the insulating film 52 may satisfactorily be set to be the compression stress film.

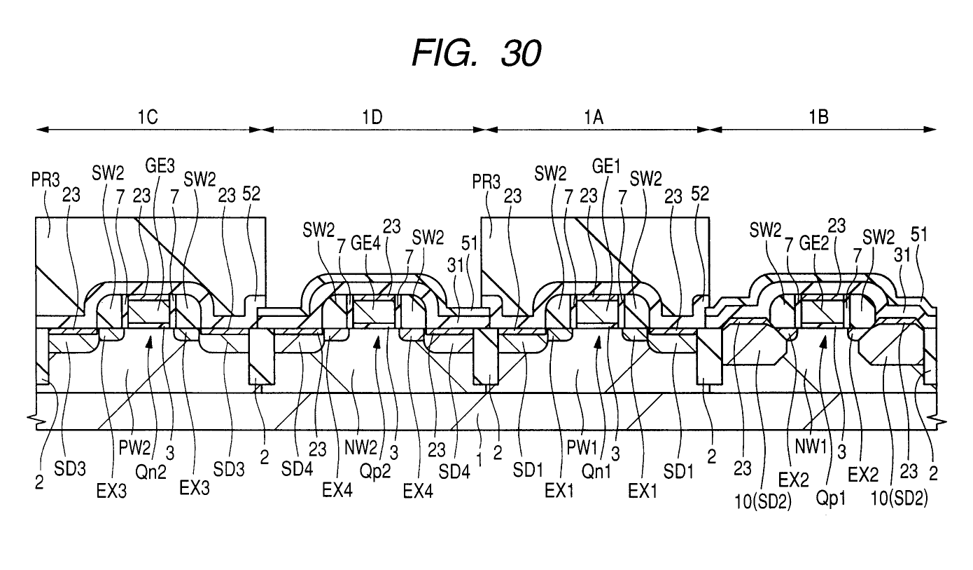

Next, as shown in FIG. 30, a photoresist film PR3, which covers the logic nMIS region 1A and the memory nMIS region 1C and exposes the logic pMIS region 1B and the memory pMIS region 1D, is formed using the photolithographic method. Then, the photoresist film PR3 is used as an etching mask to dry-etch and remove the insulating film 52 lying in the logic pMIS region 1B and memory pMIS region 1D. In the dry etching process, the insulating film 51 functions as an etching stopper.

That is, in the dry etching process in FIG. 30, since the photoresist film PR3 functions as the etching mask, the insulating film 52 in the logic nMIS region 1A and memory nMIS region 1C is not etched but left. Moreover, in the dry etching process in FIG. 30, the dry etching of the insulating film 52 is performed under an etching condition that etches the insulating film 52 easier than the insulating film 51 to enable the insulating film, 51 to function as an etching stopper film. In the logic pMIS region 1B and the memory pMIS region 1D not covered with the photoresist film PR3, therefore, the insulating film 51 and the insulating film 31 under it are left. Consequently, the metal silicide layer 23 is not exposed in any of the logic nMIS region 1A, the logic pMIS region 1B, the memory nMIS region 1C and the memory pMIS region 1D. In the dry etching process in FIG. 30, since the insulating film 51 functions as the etching stopper (an etching protective film of the insulating film 31), it is possible to prevent the etching of the insulating film 31 and to prevent the decrease in the thickness of the insulating film 31. After the dry etching process in FIG. 30, the photoresist film PR3 is removed by ashing or the like.

Moreover, in the dry etching process in FIG. 30, a part (an upper layer portion) of the insulating film 51 is possibly etched (removed) by overetching in the logic pMIS region 1B and memory pMIS region 1D. But, it is preferable that, at the stage of the end of the dry etching process in FIG. 30, at least a part of the insulating film 51 (a lower layer portion) is left in a layer shape over the insulating film 31 in the logic pMIS region 1B and memory pMIS region 1D not to expose the insulating film 31. This may surely prevent the etching of the insulating film 31 in the dry etching process in FIG. 30.

Meanwhile, when the insulating film 51 is the compression stress film instead of the tensile stress film (that is, when the insulating film 31 is the tensile stress film instead of the compression stress film), it is designed so that the photoresist film PR3 covers the logic pMIS region 1B and the memory pMIS region 1D and exposes the logic nMIS region 1A and the memory nMIS region 1C. And, the insulating film 52 lying in the logic nMIS region 1A and memory nMIS region 1C is satisfactorily dry-etched and removed by using the photoresist film PR3 as the etching mask and allowing the insulating film 51 to function as the etching stopper.

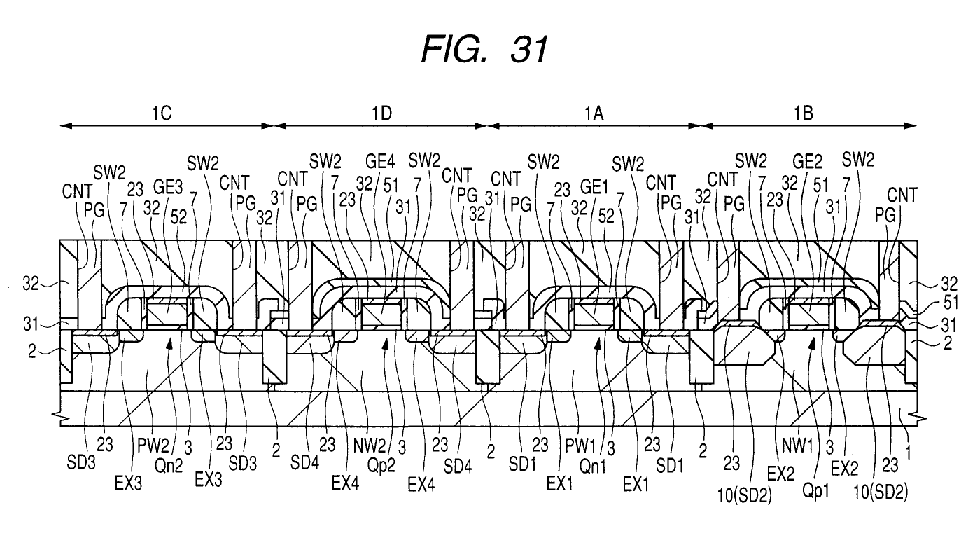

Subsequent processes are approximately the same as those in Example 1. That is, as shown in FIG. 31, the interlayer insulating film 32 is formed over the whole main surface of the semiconductor substrate 1, that is, over the main surface of the semiconductor substrate 1 including the logic nMIS region 1A, the logic pMIS region 1B, the memory nMIS region 1C and the memory pMIS region 1D. The interlayer insulating film 32 is formed over the laminated film of the insulating film 51 and the insulating film 31 and over the insulating film 52, and the thickness of the interlayer insulating film 32 is thicker than each thickness of the insulating films 31, 51 and 52. After forming the interlayer insulating film 32, the upper surface of the interlayer insulating film 32 is flattened by polishing the surface of the interlayer insulating film 32 by a CMP method, or the like.

Next, by the dry etching using a photoresist pattern (not shown) formed over the interlayer insulating film 32 as the etching mask, the contact hole CNT is formed. On this occasion, in the logic nMIS region 1A and the memory nMIS region 1C, in the laminated film constituted by the interlayer insulating film 32 and the insulating film 52, the contact hole CNT that penetrates through the laminated film is formed, and, in the logic pMIS region 1B and the memory pMIS region 1D, in the laminated film constituted by the interlayer insulating film 32, the insulating film 51 and the insulating film 31, the contact hole CNT that penetrates through the laminated film is formed.

The contact hole CNT may be formed as follows. Firstly, the contact hole CNT is formed in the interlayer insulating film 32 in the logic nMIS region 1A and the memory nMIS region 1C, and in the interlayer insulating film 32 and the insulating film 51 in the logic pMIS region 1B and the memory pMIS region 1D, by performing the dry etching of the interlayer insulating film 32 under a condition that allows the interlayer insulating film 32 and the insulating film 51 to be etched easier than the insulating films 31 and 52 to enable the insulating film 31 and the insulating film 52 to function as the etching stopper film. Then, by dry-etching and removing the insulating film 52 at the bottom portion of the contact hole CNT in the logic nMIS region 1A and the memory nMIS region 1C, and the insulating film 31 at the bottom portion of the contact hole CNT in the logic pMIS region 1B and the memory pMIS region 1D under a condition that allows the insulating films 31 and 52 to be etched easier than the interlayer insulating film 32 and the insulating film 51, the contact hole CNT as a through hole is formed.

Next, in the same manner as that in Example 1, the electroconductive plug PG is formed in the contact hole CNT.

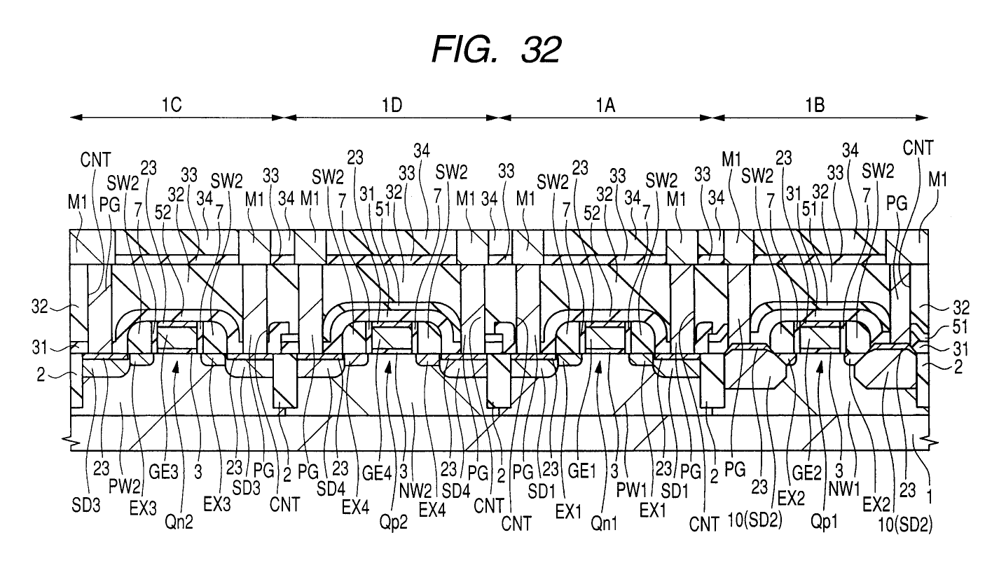

After that, in the same manner as that in Example 1, as shown in FIG. 32, the stopper insulating film 33 and the insulating film 34 are formed, and, then, in the laminated film of the stopper insulating film 33 and the insulating film 34, a wiring trench is formed, and, in the wiring trench, the wiring M1 is formed. After that, wirings subsequent to the first layer wiring are formed by the dual damascene method or the like, but the illustration and explanation thereof are omitted here.

In the semiconductor device of the present. Embodiment that is manufactured as described above, as shown in FIG. 32, the insulating film 52 being the tensile stress film is formed over the semiconductor substrate 1 so as to cover the n-channel type MISFETs Qn1 and Qn2 in the logic nMIS region 1A and the memory nMIS region 1C, that is, to cover the gate electrodes GE1 and GE3, and the n⁺-type semiconductor regions SD1 and SD3. Moreover, the insulating film 31 being the compression stress film is formed over the semiconductor substrate 1 so as to cover the p-channel type MISFETs Qp1 and Qp2 in the logic pMIS region 1B and the memory pMIS region 1D, that is, to cover the gate electrodes GE2 and GE4, and the p⁺-type semiconductor regions SD2 and SD4.

The present Example may give following effects in addition to the effect obtained in Example 1. That is, in the present Example, since the tensile stress caused by the tensile stress film (here, the insulating film 52) is applied to the channel regions of the n-channel type MISFETs Qn1 and Qn2 formed in the logic nMIS region 1A and the memory nMIS region 1C, the mobility of carriers (electrons) in the channel region may be improved. Moreover, since the compression stress caused by the compression stress film (here, the insulating film 31) is applied to the channel regions of the p-channel type MISFETs Qp1 and Qp2 formed in the logic pMIS region 1B and the memory pMIS region 1D, the mobility of carriers (holes) in the channel region may be improved. As the result, it is possible to further improve the ON current of both the n-channel type MISFETs Qn1 and Qn2 in the logic nMIS region 1A and memory nMIS region 1C, and the p-channel type MISFETs Qp1 and Qp2 in the logic pMIS region 1B and memory pMIS region 1D.

Moreover, by allowing the insulating film 51 to function as the etching stopper (the etching protective film of the insulating film 31) in the dry etching process in FIG. 30 (the process of removing the insulating film 52), it is possible to prevent the etching of the insulating film 31, and to prevent the decrease in the thickness of the insulating film 31. As the result, the thickness of the insulating film 31 in the manufactured semiconductor device preserves the thickness of the deposited film. Since the deposited film thickness when a film is formed over a semiconductor wafer may be controlled with high accuracy, when the thickness of the insulating film 31 may preserve the deposited film thickness as in the Example, it is possible to set the thickness of the insulating film 31 in the manufactured semiconductor device approximately to be a designed value itself, which may set the stress value acting on the MISFET approximately to be a designed value. Moreover, since the thickness of the insulating film 31 may preserve the deposited film thickness, it is possible to suppress the variation in the thickness of the insulating film 31 every wafer, and to suppress the variation in properties of the MISFET among wafers.

Until now, the invention achieved by the present inventor has specifically been explained on the basis of Examples thereof, however, needless to say, the present invention is not limited to the Example but may variously be changed within the range that does not depart from the gist thereof.

The present invention is effective when it is applied to semiconductor devices and the manufacturing technique thereof.

What is claimed is:

1. A semiconductor device comprising: a plurality of p-channel type field effect transistors for logic; a plurality of n-channel type field effect transistors for logic; and a plurality of p-channel type field effect transistors for memory mixedly mounted over a semiconductor substrate, wherein:
at least a part of the p-channel type field effect transistors for logic have each a first source/drain region constituted by silicon-germanium;
all the n-channel type field effect transistors for logic have each a second source/drain region constituted by silicon; and
all the p-channel type field effect transistors for memory have each a third source/drain region constituted by silicon.

2. The semiconductor device according to claim 1 further comprising a plurality of n-channel type field effect transistors for memory formed over the semiconductor substrate, wherein
all the n-channel type field effect transistors for memory have each a fourth source/drain region constituted by silicon.

3. The semiconductor device according to claim 2, wherein among the p-channel type field effect transistors for logic, the p-channel type field effect transistor for logic used in an arithmetic circuit has the first source/drain region constituted by silicon-germanium.

4. The semiconductor device according to claim 3, wherein
the semiconductor substrate is a silicon substrate, and has the surface orientation in a (100) orientation.

5. The semiconductor device according to claim 4, wherein
the p-channel type field effect transistor for logic having the first source/drain region constituted by silicon-germanium has the gate length direction of a channel region in a <110> direction.

6. The semiconductor device according to claim 5, wherein:
a metal silicide layer is formed, respectively, over the second source/drain regions of the n-channel type transistors for logic and over the fourth source/drain regions of the n-channel type field effect transistors for memory; and
the metal silicide layer contains at least one kind of metal element selected from the group having Pt, Pd, Hf, V, Al, Er, Yb and Co, and Ni.

7. The semiconductor device according to claim 6, wherein
the n-channel type field effect transistors for logic and the n-channel type field effect transistors for memory include an n-channel type field effect transistor having the gate length direction of a channel region in a <110>direction.

8. The semiconductor device according to claim 7, wherein:
the second, third and fourth source/drain regions constituted by silicon are formed by introducing an impurity into the semiconductor substrate; and
the first source/drain region constituted by silicon-germanium is formed from silicon-germanium epitaxially grown in a trench formed in the semiconductor substrate.

9. The semiconductor device according to claim 8, wherein
the metal silicide layer has the metal element segregated near the interface with the semiconductor substrate constituted by silicon.

10. The semiconductor device according to claim 9, wherein
the metal element is Pt.

11. The semiconductor device according to claim 10, further comprising: a compression stress film formed over the semiconductor substrate so as to cover the p-channel type field effect transistors for logic and the p-channel type field effect transistors for memory; and a tensile stress film formed over the semiconductor substrate so as to cover the n-channel type field effect transistors for logic and the n-channel type field effect transistors for memory.

12. A method of manufacturing a semiconductor device having a p-channel type field effect transistor for logic in a first logic region of a semiconductor substrate, an n-channel type field effect transistor for logic in a second logic region of the semiconductor substrate, a p-channel type field effect transistor for memory in a first memory region of the semiconductor substrate, and an n-channel type field effect transistor for memory in a second memory region of the semiconductor substrate, the method comprising the steps of:
(a) preparing the semiconductor substrate;
(b) after the step (a), forming a first gate electrode of the p-channel type field effect transistor for logic in the first logic region, a second gate electrode of the n-channel type field effect transistor for logic in the second logic region, a third gate electrode of the p-channel type field effect transistor for memory in the first memory region, and a fourth gate electrode of the n-channel type field effect transistor for memory in the second memory region over the semiconductor substrate via a gate insulating film, respectively;
(c) forming a trench in the first logic region and epitaxially growing a silicon-germanium region in the trench to form a first source/drain region constituted by silicon-germanium of the p-channel type field effect transistor for logic; and
(d) forming a second source/drain region of the n-channel type field effect transistor for logic in the second logic region, a third source/drain region of the p-channel type field effect transistor for memory in the first memory region, and a fourth source/drain region of the n-channel type field effect transistor for memory in the second memory region by ion-implanting an impurity into the semiconductor substrate, respectively, wherein
the trench and the silicon-germanium region are formed in the first logic region, but are not formed in the second logic region, the first memory region, or the second memory region.

13. The method of manufacturing a semiconductor device according to claim 12, wherein:
the semiconductor substrate is a silicon substrate, and has the surface orientation in a (100) orientation; and
the p-channel type field effect transistor for logic has the gate length direction of a channel region in a <110> direction.

14. The method of manufacturing a semiconductor device according to claim 13, further comprising the steps of:
(e) after the step (d), forming a nickel alloy film over the semiconductor substrate including over the second and fourth source/drain regions;
(f) after the step (e), performing a first heat treatment to react the nickel alloy film with the second and fourth source/drain regions, and thereby forming a metal silicide layer over the second and fourth source/drain regions;
(g) after the step (f), removing the nickel alloy film that did not react in the step (f); and
(h) after the step (g), performing a second heat treatment at a heat treatment temperature higher than that in the first heat treatment to further react the metal silicide layer with the second and fourth source/drain regions.

15. The method of manufacturing a semiconductor device according to claim 14, wherein
the nickel alloy film is an alloy film of at least one kind of element selected from the group having Pt, Pd, Hf, V, Al, Er, Yb and Co, and Ni.

16. The method of manufacturing a semiconductor device according to claim 15, wherein
the nickel alloy film is a nickel platinum alloy film.

17. The method of manufacturing a semiconductor device according to claim 16, wherein:
the first heat treatment in the step (f) has a heat treatment temperature within the range of 200 to 300° C., and a heat treatment time within the range of 10 to 60 seconds; and
the second heat treatment in the step (h) has a heat treatment temperature within the range of 400 to 600° C., and a heat treatment time of 30 seconds or less.

18. The method of manufacturing a semiconductor device according to claim 17, wherein:
the first heat treatment in the step (f) has a heat treatment temperature within the range of 240 to 280° C.; and
the second heat treatment in the step (h) has a heat treatment temperature within the range of 500 to 550° C.

19. The method of manufacturing a semiconductor device according to claim 18, wherein
the platinum concentration in the nickel alloy film is 3 to 7 atom %.

20. The method of manufacturing a semiconductor device according to claim 19, further comprising the step of
after the step (h), forming a tensile stress film or a compression stress film over the semiconductor substrate.

21. The method of manufacturing a semiconductor device according to claim 20, wherein
the metal silicide layer at the stage of performing the first heat treatment in the step (f), and the metal silicide layer at the stage of performing the second heat treatment in the step (h) have Pt segregated near the interface with the semiconductor substrate constituted by silicon.
